(19) United States
(12) Patent Application Publication
(10) Pub. No.: US 2025/0095606 A1
(43) Pub. Date: Mar. 20, 2025

(54) DISPLAY DRIVER SYSTEM WITH EMBEDDED NON-VOLATILE MEMORY

(71) Applicant: HEFEI RELIANCE MEMORY LIMITED, Hefei (CN)

(72) Inventors: Liang ZHAO, SUNNYVALE, CA (US); Zhichao LU, SAN JOSE, CA (US); Zhigang HAN, NONTHABURI (TH)

(21) Appl. No.: 18/923,462

(22) Filed: Oct. 22, 2024

Related U.S. Application Data
(63) Continuation-in-part of application No. 18/374,541, filed on Sep. 28, 2023.
Application No. 18/374,541 is a continuation-in-part of application No. 18/083,355, filed on Dec. 16, 2022, now Pat. No. 12,142,241.
Application No. 18/083,355 is a continuation of application No. 16/842,385, filed on Apr. 7, 2020, now Pat. No. 11,557,264.
(60) Provisional application No. 62/832,224, filed on Apr. 10, 2019.

(51) Int. Cl. G09G 5/00; G11C 7/10; H04N 5/57

(52) U.S. Cl. CPC G09G 5/006; G11C 7/10; G09G 2320/0233; H04N 5/57

(57) ABSTRACT

Circuitry for adjusting luminance of a display device is provided. The circuitry includes a non-volatile memory array having a plurality memory cells configured to store luminance data of the display device, and a luminance adjusting circuit configured to receive image data to be displayed on the display device. The luminance adjusting circuit is coupled directly to the non-volatile memory array to receive the luminance data of the display device from the non-volatile memory array and adjust the image data based on the luminance data of the display device.

### CROSS REFERENCE TO RELATED APPLICATIONS

This application is a continuation-in-part of U.S. patent application Ser. No. 18/374,541 filed Sep. 28, 2023, entitled “DISPLAY DRIVER SYSTEM WITH EMBEDDED NON-VOLATILE MEMORY,” which is a continuation-in-part of U.S. patent application Ser. No. 18/083,355 filed Dec. 16, 2022, entitled “DISPLAY DRIVER SYSTEM WITH EMBEDDED NON-VOLATILE MEMORY”, which is a continuation of U.S. patent application Ser. No. 16/842,385 filed Apr. 7, 2020, entitled “DISPLAY DRIVER SYSTEM WITH EMBEDDED NON-VOLATILE MEMORY”, now U.S. Pat. No. 11,557,264, which claims benefits of U.S. provisional application No. 62/832,224 filed Apr. 10, 2019, entitled “OLED DISPLAY DRIVER SYSTEM WITH EMBEDDED NVM,” the contents of which are incorporated by reference herein in their entirety.

### TECHNICAL FIELD

The disclosure relates generally to integrated circuits, and more specifically to display drivers.

### BACKGROUND

Display driver integrated circuits (DDIC) includes a class of integrated circuits that provide interface functions between a particular microprocessor/microcontroller/application-specific integrated circuit (ASIC)/interface, and a particular display device including but not limited to a liquid crystal display (LCD), a light emitting diode (LED) display, an organic light emitting diode (OLED) display, etc. The display driver typically accepts commands and data through an industry-standard general-purpose interface, and generates signals with a suitable voltage/current/timing to make the display show the desired images.

OLED displays are entering mainstream mobile devices. For such applications, DDICs are expected to be low-cost and have small form-factor and high performance. FIG. 1 is a block diagram illustrating a conventional display driver system 100. The display driver system 100 includes a mobile industry processor interface (MIPI) 102, a digital signal compression (DSC) encoder 104, a data buffer (Dbuf) 106, a static random access memory (SRAM) 108, a DSC decoder 110, a screen color management (SCM) block 112, a fringe adjustment block 114, a sub-pixel rendering (SPR) block 116, a de-mura block 118, a flash memory 120, another SRAM 122, a de-gamma (gamma correction) block 124, a timing control (T-con) block 126, an analog circuit 128, a general purpose input/output (GPIO) interface 130, and a display panel 132.

The MIPI 102 defines a serial bus and a communication protocol between the host (source of the image data) and the display system 100 (destination of the image data). The MIPI 102 may forward the received image/pixel data to the DSC encoder 104 and the data buffer 106. The DSC encoder 104 is configured to encode/compress pixel data using a DSC standard, and send the encoded pixel data to the data buffer 106. The data buffer 106 temporarily stores the pixel data compressed with the DSC standard in the SRAM 108. The compressed pixel data is then sequentially forwarded to DSC decoder 110, which decodes the next available pixel data with the DSC standard into pixel/RGB data. The screen color management block 112 receives the RGB data/signals and translates the color from the original color space to a designated color space (designated either by a designer or user) associated with the display panel 132 (e.g., an OLED display).

The fringe adjustment block 114 is configured to process the pixel data based on a particular shape (e.g., the bezel/notch part) of the display panel 132, such as a display for a mobile device. For example, the fringe adjustment block 114 may remove some pixel data at the edge/fringe portions of an image such that the image can be properly displayed on a mobile phone. The sub-pixel rendering block 116 is configured to increase the apparent resolution of the display panel 132 by separately rendering RGB pixels using the underlying physical properties of the display panel 132.

The de-mura block 118 is configured to calibrate the luminance data across the screen and use the data to calculate individual correction to each pixel, in order to achieve more uniform luminance/appearance of the display panel 132. Due to manufacturing variations, each pixel of the display panel 132 may have a slight luminance difference from each other given a same driving condition. For example, when all pixels of the display panel 132 are given a same driving voltage or current, the pixels may exhibit different brightness, thus degrading the visual experience for a user. The de-mura block 118 is designed to correct such variations. To achieve that, the display system 100 further contains a flash memory 120 and an SRAM 122. The flash memory 120 is configured to store mura information for the display panel 132. For example, the mura information is generated based on a luminance measure for each individual display panel. The mura information is written into the flash memory 120 via an input/output 120-1 of the flash memory 120. When the display panel 132 is powered on, the data is read from the flash memory 120 into the SRAM 122. When image data is read at the de-mura block 118, the mura information is output via the SRAM's input/output 122-1 to the de-mura block 118, which then use the mura information to calibrate the luminance data of the image data.

The de-gamma block 124 is configured to transform frame/image data and accommodate the non-linear relationship between the luminance and the input voltage. The image data is then sent to the T-Con block 126 and the analog circuit 128. The T-Con block 126 is a control circuit for the analog circuit 128, which generates voltages/currents for driving the pixels of the display panel 132. The driving signals from the analog circuit 128 are sent to the display panel 132 via the GPIO interface 130 to drive the pixels of the display panel 132.

### SUMMARY

In general, one aspect disclosed features an apparatus comprising: circuitry for adjusting luminance of a display device, comprising: a non-volatile memory array having a plurality of memory cells configured to store luminance data of the display device, and a luminance adjusting circuit configured to receive image data to be displayed on the display device and adjust the image data based on the luminance data of the display device; and a unified controller configured to provide (i) memory control signals to control operations of the non-volatile memory array and (ii) luminance control signals to control operations of the luminance adjusting circuit.

Embodiments of the apparatus may include one or more of the following features. In some embodiments, the unified controller comprises: a single finite state machine configured to generate (i) the memory control signals and (ii) the luminance control signals. In some embodiments, the circuitry for adjusting luminance of a display device further comprises a further non-volatile memory array having a further plurality of memory cells configured to buffer the image data prior to the luminance adjusting circuit adjusting the image data; and the unified controller is further configured provide (iii) further memory control signals to control operations of the further non-volatile memory array. In some embodiments, the unified controller comprises: a single finite state machine configured to generate (i) the memory control signals, (ii) the luminance control signals, and (iii) the further memory control signals. Some embodiments comprise a single integrated circuit comprising the apparatus.

In some embodiments, the non-volatile memory array includes one of a resistive random-access memory, a phase-change random access memory, a ferroelectric random-access memory, or a spin-transfer torque magnetic random-access memory. In some embodiments, the non-volatile memory array is a one-time programmable memory. In some embodiments, the non-volatile memory array includes a redundant memory section configured to correct an error of the luminance data after the one-time programmable memory is programmed with the luminance data. In some embodiments, the non-volatile memory array includes a plurality of memory banks, and wherein the luminance adjusting circuit is configured to receive in parallel a set of data from the plurality of memory banks and output in series pixel data corresponding to the set of data. In some embodiments, the unified controller comprises: a non-volatile memory, the unified controller configured to provide the memory control signals and the luminance control signals in accordance with data stored in the non-volatile memory.

In general, one aspect disclosed features an apparatus comprising: circuitry for adjusting luminance of a display device, comprising: a non-volatile memory array having a plurality of memory cells configured to store luminance data of the display device, and a luminance adjusting circuit configured to receive image data to be displayed on the display device and adjust the image data based on the luminance data of the display device; a luminance controller comprising a first non-volatile memory, the luminance controller configured to provide luminance control signals to control operations of the luminance adjusting circuit in accordance with first data stored in the first non-volatile memory; and a memory controller comprising a second non-volatile memory, the memory controller configured to provide memory control signals to control operations of the non-volatile memory array in accordance with second data stored in the second non-volatile memory.

Embodiments of the apparatus may include one or more of the following features. In some embodiments, the luminance controller comprises: a single finite state machine configured to generate the luminance control signals. In some embodiments, the memory controller comprises: a single finite state machine configured to generate the memory control signals. In some embodiments, the circuitry for adjusting luminance of a display device further comprises a further non-volatile memory array having a further plurality of memory cells configured to buffer the image data prior to the luminance adjusting circuit adjusting the image data; and the memory controller is further configured provide further memory control signals to control operations of the further non-volatile memory array. In some embodiments, the memory controller comprises: a single finite state machine configured to generate the memory control signals and the further memory control signals. Some embodiments comprise a single integrated circuit comprising the apparatus.

In some embodiments, the non-volatile memory array includes one of a resistive random-access memory, a phase-change random access memory, a ferroelectric random-access memory, or a spin-transfer torque magnetic random-access memory. In some embodiments, the non-volatile memory array is a one-time programmable memory. In some embodiments, the non-volatile memory array includes a redundant memory section configured to correct an error of the luminance data after the one-time programmable memory is programmed with the luminance data. In some embodiments, the non-volatile memory array includes a plurality of memory banks, and wherein the luminance adjusting circuit is configured to receive in parallel a set of data from the plurality of memory banks and output in series pixel data corresponding to the set of data.

One aspect of the present disclosure is directed to circuitry for adjusting luminance of a display device. The circuitry includes a non-volatile memory array having a plurality memory cells configured to store luminance data of the display device, and a luminance adjusting circuit configured to receive image data to be displayed on the display device. The luminance adjusting circuit is coupled directly to the non-volatile memory array to obtain the luminance data of the display device from the non-volatile memory array and adjust the image data based on the luminance data of the display device.

Embodiments of the circuitry may include one or more of the following features. In some embodiments, the circuitry further includes a memory control circuit coupled to the non-volatile memory array and configured to control operations of the non-volatile memory array. In some embodiments, the circuitry further includes an input/output interface coupled to the memory control circuit and configured to receive the luminance data from outside of the circuitry. In some embodiments, the memory control circuit and the input/output interface are embedded in the luminance adjusting circuit. In some embodiments, the non-volatile memory array includes one of a resistive random-access memory, a phase-change random access memory, a ferroelectric random-access memory, or a spin-transfer torque magnetic random-access memory.

In some embodiments, the non-volatile memory array is a one-time programmable memory. In some embodiments, the non-volatile memory array includes a redundant memory section configured to correct an error of the luminance data after the one-time programmable memory is programmed with the luminance data. In some embodiments, the non-volatile memory array includes a plurality of memory banks, and the luminance adjusting circuit is configured to receive in parallel a set of data from the plurality of memory banks and output in series pixel data corresponding to the set of data.

In another aspect, a display control circuit is provided. The display control circuit includes an input interface configured to receive image data to be displayed on a display device; circuitry configured to adjust the image data to generate adjusted image data; and an output interface configured to output to the display device display signals generated based on the adjusted image data. The circuitry includes a non-volatile memory array having a plurality memory cells configured to store luminance data of the display device, and a luminance adjusting circuit configured to receive the image data to be displayed on the display device. The luminance adjusting circuit is coupled directly to the non-volatile memory array to obtain the luminance data of the display device from the non-volatile memory array and adjust the image data based on the luminance data of the display device.

In some embodiments, the display control circuit further includes a digital signal compression encoder coupled to the input interface and configured to encode the image data received from the input interface to generate encoded image data, a data buffer coupled to the digital signal compressing encoder and the input interface, the data buffer being configured to store the encoded image data and the image data, and a digital signal compression decoder coupled to the data buffer and configured to decode the encoded image data.

In some embodiments, the data buffer includes a non-volatile memory device. In some embodiments, the non-volatile memory device is a multiple-time programmable memory device. In some embodiments, the non-volatile memory device includes one of a resistive random access memory device, a phase-change random access memory device, a ferroelectric random access memory device, or a spin-transfer torque magnetic random access memory device.

These and other features of the apparatuses, systems, and methods, disclosed herein, as well as the methods of operation and functions of the related elements of structure, will become more apparent upon consideration of the following description and the appended claims with reference to the accompanying drawings, all of which form a part of this specification. It is to be expressly understood, however, that the drawings are for purposes of illustration and description only and are not intended as a definition of the limits of the disclosure. It is to be understood that the foregoing general description and the following detailed description are exemplary and explanatory only, and are not restrictive of the disclosure, as claimed.

### BRIEF DESCRIPTION OF THE DRAWINGS

Non-limiting embodiments of the disclosure may be more readily understood by referring to the following drawings.

FIG. 1 is a block diagram illustrating a conventional display driver system.

FIG. 2 is a block diagram of a display device, according to an example embodiment.

FIG. 3 is a block diagram illustrating a display control device for controlling luminance of a display device according to an example embodiment.

FIG. 4 is a block diagram illustrating another display control device for controlling luminance of a display device according to an example embodiment.

FIG. 5 is a block diagram illustrating another display control device for controlling luminance of a display device according to an example embodiment.

FIG. 6 is a block diagram illustrating yet another display control device for controlling luminance of a display device according to an example embodiment.

FIG. 7 is a block diagram illustrating a display control device having a display data buffer device for controlling luminance of a display device according to an example embodiment.

FIG. 8 is a block diagram illustrating a conventional display system with a single controller according to an example embodiment.

FIG. 9 is a block diagram illustrating a display system having two controllers according to an example embodiment.

FIG. 10 is a block diagram illustrating a display system having a unified DDIC/NVM controller according to an example embodiment.

FIG. 11 is a block diagram illustrating a display system having two controllers with NVM according to an example embodiment.

FIG. 12 is a block diagram illustrating a display system having a unified DDIC/NVM controller with NVM according to an example embodiment.

FIG. 13 is a block diagram illustrating a display driver system embedded with NVM for HMDs according to an example embodiment.

FIG. 14 is a block diagram illustrating a display driver system embedded with Non-Volatile Memory (NVM) controlled by a unified controller according to an example embodiment.

FIG. 15 is a block diagram illustrating an example display driver system using embedded NVM to store deburn-in correction data, offering several technical improvements over traditional SRAM-based solutions.

FIG. 16 is a block diagram illustrating a conventional display driver chip for AOD.

FIG. 17 is a block diagram illustrating an NVM-based display driver integrated circuits (DDIC) for AOD, according to an example embodiment.

FIG. 18 is a block diagram illustrating a conventional touch and display driver integrated chip (TDDI) with embedded RAM.

FIG. 19 is a block diagram illustrating an enhanced Touch and Display Driver Integrated Chip (TDDI) with embedded Non-Volatile Memory (NVM) according to an example embodiment.

### DETAILED DESCRIPTION OF THE EMBODIMENTS

Non-limiting embodiments of the present disclosure will now be described with reference to the drawings. It should be understood that particular features and aspects of any embodiment disclosed herein may be used and/or combined with particular features and aspects of any other embodiment disclosed herein. It should also be understood that such embodiments are by way of example and are merely illustrative of a small number of embodiments within the scope of the present disclosure. Various changes and modifications obvious to one skilled in the art to which the present disclosure pertains are deemed to be within the spirit, scope and contemplation of the present disclosure as further defined in the appended claims.

Mura/unevenness effect in luminance is common to display devices. For example, for OLED displays, each pixel is an individual light emitter and pixel-to-pixel variations can cause non-uniform luminance across the screen/panel, a.k.a. mura. This effect causes visual unevenness to a user and needs to be mitigated. Generally, during OLED manufacturing/testing processes, the luminance data across a screen can be measured and recorded. These data can be used to calculate individual correction of applied voltage/current to each pixel, resulting in uniform appearance of the display. The process is called mura correction, or de-mura. The luminance non-uniformity is recorded once for each screen, and typically would not change significantly during the service life of the screen. The memory capacity for de-mura purposes is proportional to the total number of pixels of the screen.

Techniques disclosed herein provide solutions in which memory for a de-mura block can be fast programmed and read, and have good data retention (at least 85° C. for 10 years), low power consumption during read, and small form factor for mobile applications.

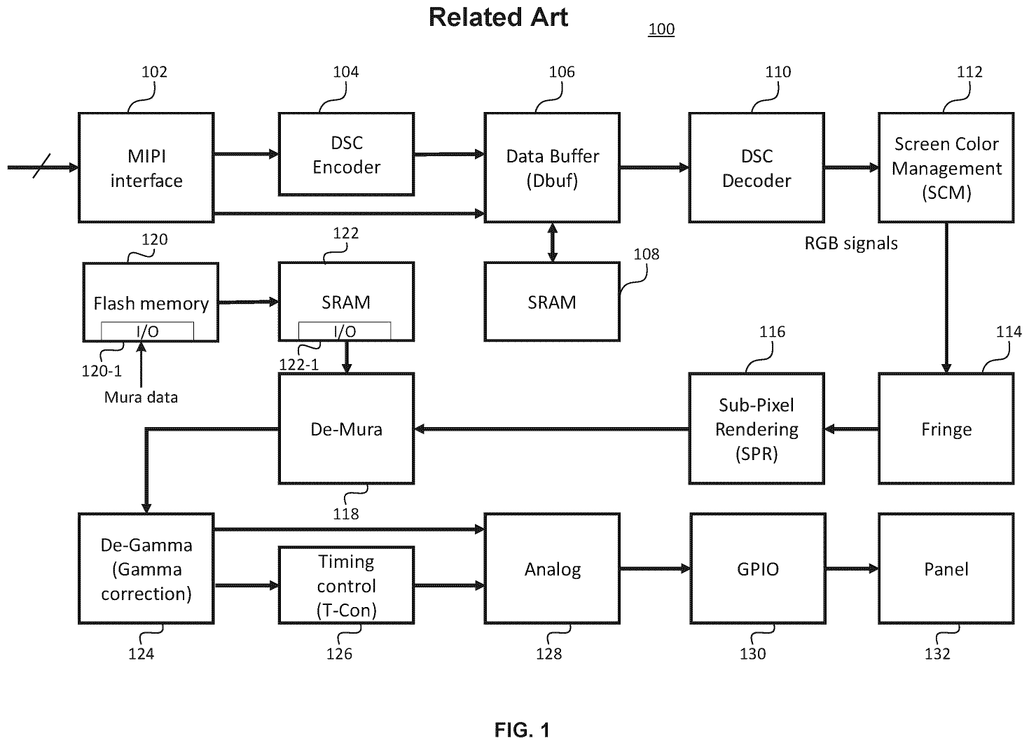

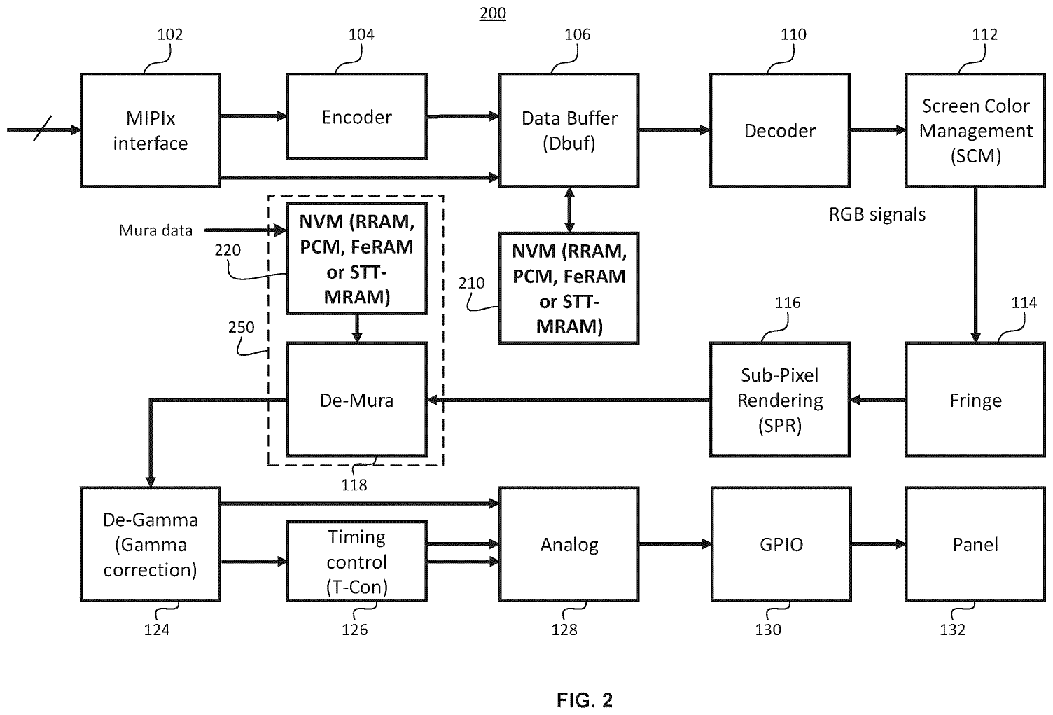

Example embodiments will be explained below with accompanying figures. Reference is now made to FIG. 2. FIG. 2 is a block diagram of a display device 200, according to an example embodiment. The display device 200 is similar to the display device 100 of FIG. 1 except that the display device 200 uses a first non-volatile memory (NVM) device 210 coupled to the data buffer 106, and a second non-volatile memory (NVM) device 220 coupled to the de-mura block 118. As other components of the display device 200 are similar to those of the display device 100, detailed description of those components will not be provided again. The de-mura block 118 and the second non-volatile memory (NVM) device 220 form a circuit 250 for adjusting luminance of a display device. For example, the circuit 250 is configured to correct mura effect for the display panel 132 of the display device 200.

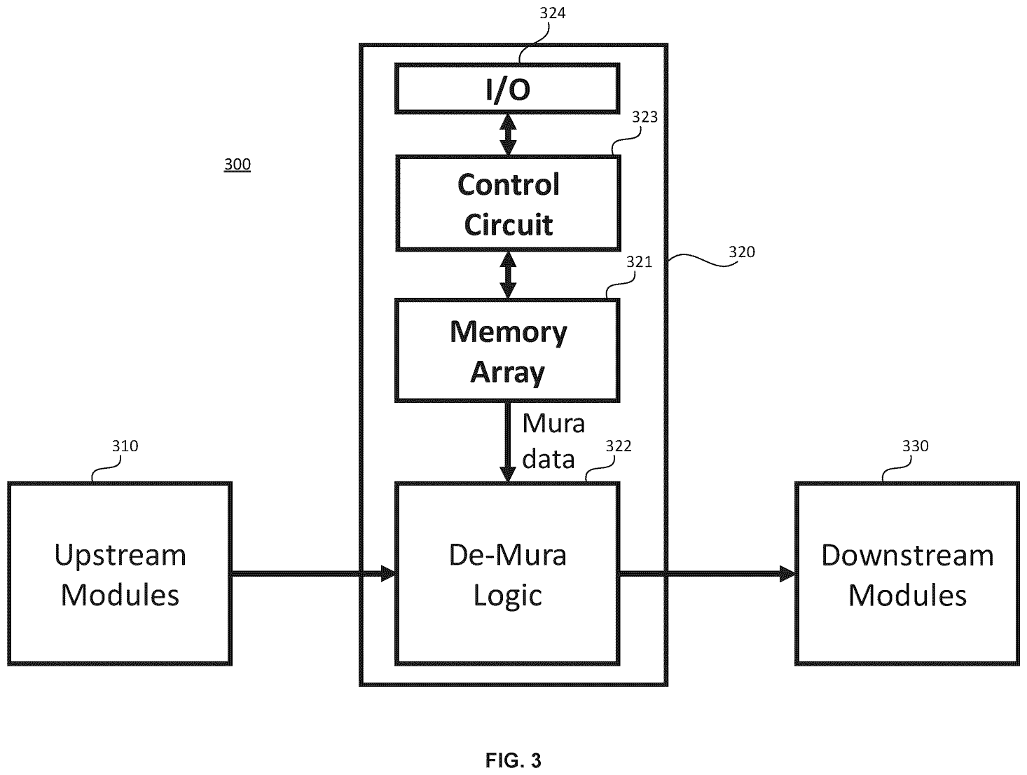

FIG. 3 is a block diagram illustrating a display control device 300 for controlling luminance of a display device according to an example embodiment. The display control device 300 includes one or more upstream modules 310, circuitry 320, and one or more downstream modules 330. The upstream modules 310 are configured to receive and process image data for pixels of a display device. The display device may be an LCD, LED, or OLED panel, or other display panels currently known or hereinafter developed. The circuitry 320 is configured to adjust luminance of the display device. In some embodiments, the circuitry 320 is configured to adjust luminance of the display device to correct mura effects on the display device. The downstream modules 330 are configured to further process the image data from the circuitry 320 and generate, based on the image data, drive signals to drive the display device.

In some embodiments, the circuitry 320 includes a non-volatile memory array 321 having a plurality memory cells configured to store luminance/mura data of the display device. In some embodiments, the luminance data of the display device include luminance measurements for pixels of the display device. For example, the luminance data may include luminance measurements for all pixels on the display device. The circuitry 320 further includes a luminance adjusting circuit 322 configured to receive from the upstream modules 310 image data to be displayed on the display device. In the illustrated embodiment, the luminance adjusting circuit 322 may be a de-mura logic. When the luminance adjusting circuit 322 receives the image data, it obtains luminance/mura data from the memory array 321 and calibrates the image data to compensate for the unevenness of luminance across the display device, resulting in displaying an improved image on the display device. As shown in FIG. 3, the luminance adjusting circuit 322 is coupled directly to the non-volatile memory array 321 to receive the luminance data of the display device from the non-volatile memory array 321 and to adjust the image data based on the luminance data of the display device. The luminance/mura data flows one way from the non-volatile memory array 321 to the luminance adjusting circuit 322.

In some embodiments, the circuitry 320 further includes a control circuit 323 coupled to the non-volatile memory array 321 and configured to control operations of the non-volatile memory array 321. The circuitry 320 also includes an input/output (I/O) 324 coupled to the memory control circuit and configured to receive the luminance data from outside of the circuitry 320. For example, luminance/mura data of the display device is measured and written into the memory array 321 via the I/O 324. As compared to de-mura function that includes the de-mura block 118, the flash memory 120 (with its I/O 120-1), and the SRAM 122 (with its I/O 122-1), the circuitry 320 for adjusting luminance/mura effect eliminates the interface between a memory device (e.g., the memory array 321) and a de-mura logic 322. Further, the circuitry 320 includes one I/O interface 324, instead of two (I/Os 120-1 and 122-1 in FIG. 1) to obtain the luminance/mura data for the de-mura logic 322. This reduces the complexity of the circuitry for correcting the mura effect.

In some embodiments, the non-volatile memory array 321 includes one of a resistive random-access memory, a phase-change random access memory, a ferroelectric random-access memory, or a spin-transfer torque magnetic random-access memory. In some embodiments, the non-volatile memory array 321 is a one-time programmable memory. That is, non-volatile memory array 321 can be written with data only once. In some embodiments, the non-volatile memory array 321 is a multi-time programmable memory that can be reprogrammed more than one time.

In some embodiments, when the memory array 321 includes a resistive random-access memory, each of memory cells on the memory array 321 may include one transistor (T) and one resistive (R) device (1T1R). As compared to the conventional de-mura function that includes a SRAM, which generally requires six transistors in a memory cell, the memory array 321 consumes fewer chip areas. Moreover, because operation of an SRAM requires standby power, the circuitry 320 also uses less power due to no standby power for the non-volatile memory array 321. The non-volatile memory array 321 requires comparable or lower read current than an SRAM array. Further, the non-volatile memory array 321 has a faster response than an SRAM array as, in the conventional de-mura function, the luminance/mura data needs to be read from a flash memory to the SRAM array. Another advantage of the circuitry 320 is that it includes no flash memory.

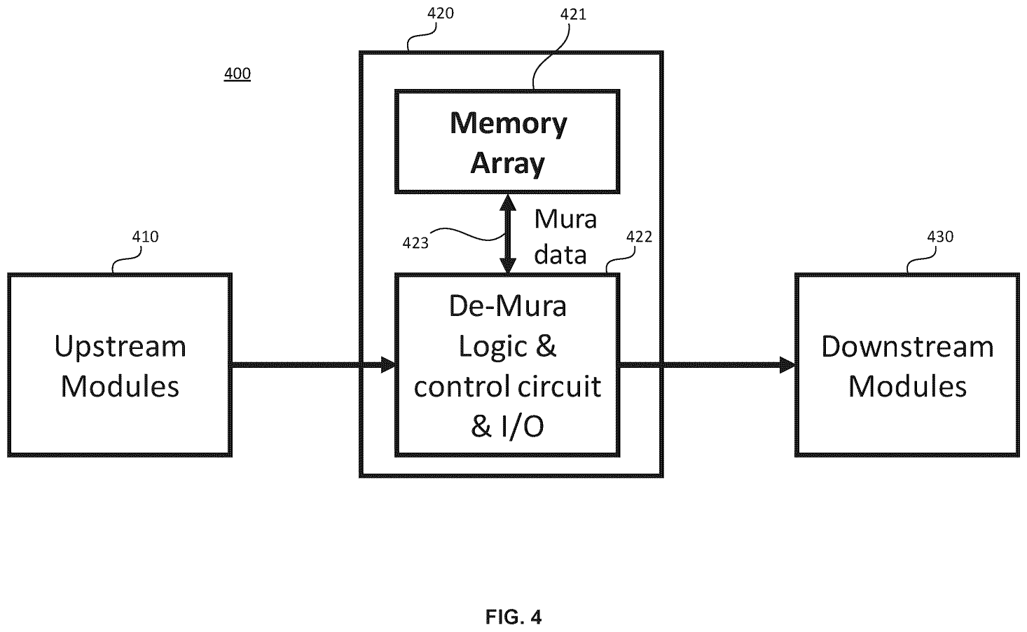

FIG. 4 is a block diagram illustrating a display control device 400 for controlling luminance of a display device according to an example embodiment. The display control device 400 includes one or more upstream modules 410, circuitry 420, and one or more downstream modules 430. The upstream modules 410 and the downstream modules 430 are similar to the upstream modules 310 and the downstream modules 330 of FIG. 3, and their functions will not be further described here. The circuitry 420 is configured to adjust luminance of the display device. In some embodiments, the circuitry 420 is configured to adjust luminance of the display device to correct mura effects on the display device.

In some embodiments, the circuitry 420 includes a non-volatile memory array 421 having a plurality memory cells configured to store luminance/mura data of the display device, and a luminance adjusting circuit 422 coupled directly to the non-volatile memory array 421 via a communication channel 423. The luminance adjusting circuit 422 includes de-mura logic for calibrating the image data to compensate for the unevenness of luminance across the display device. Further, a control circuit and an I/O interface for the non-volatile memory array 421 are embedded in the luminance adjusting circuit 422. The luminance/mura data for the display device are written into the non-volatile memory array 421 via the luminance adjusting circuit 422 that contains the control circuit and the I/O interface for the non-volatile memory array 421. When the de-mura logic of the luminance adjusting circuit 422 receives image data from the upstream modules 410, it obtains the luminance/mura data from the memory array 421 to calculate corrected pixel luminance values for the pixels of the display device.

In the circuitry 420, because the control circuit and the I/O interface for the non-volatile memory array 421 are embedded in the luminance adjusting circuit 422, there is no external I/O for the memory array 421. Further, the non-volatile memory array 421 can be programmed using the I/O interface in the luminance adjusting circuit 422. This structure eliminates the need for an external I/O for the non-volatile memory array 421 and may save cost to implement the display control device 400. Thus, two-way traffic is implemented on the communication channel 423.

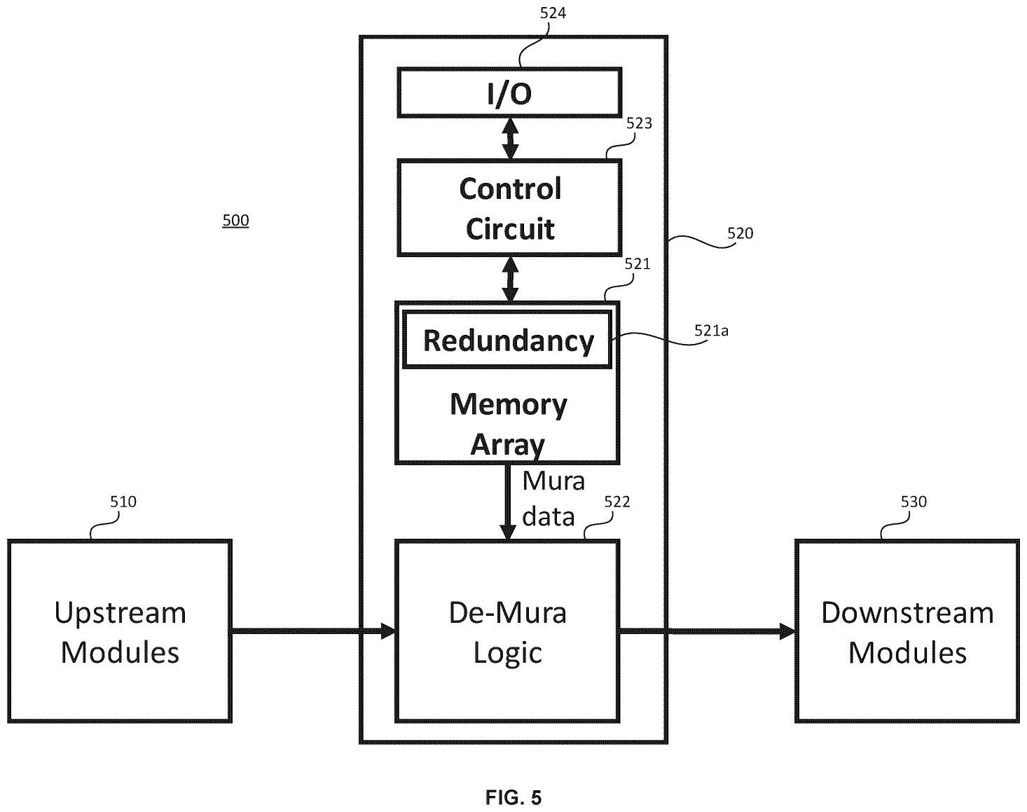

FIG. 5 is a block diagram illustrating yet another display control device 500 for controlling luminance of a display device according to an example embodiment. The display control device 500 includes one or more upstream modules 510, circuitry 520 for adjusting luminance, and one or more downstream modules 530. The circuitry 520 includes a non-volatile memory array 521, a luminance adjusting circuit 522, a control circuit 523 for controlling the non-volatile memory array 521, and an I/O interface 524.

The display control device 500 is similar to the display control device 300 in FIG. 3 except that the non-volatile memory array 521 of the display control device 500 further includes a redundant memory section 521a. The redundant memory section 521a is configured to correct an error of the luminance/mura data after the one-time programmable memory 521 is programmed with the luminance/mura data. In some instances, the luminance/mura data may be incorrectly written into the non-volatile memory array 521, or the luminance/mura data in some cells of the non-volatile memory array 521 may be lost due to, e.g., faulty cells. When this happens, the data stored at the redundant memory section 521a may be employed to correct the errors after the luminance/mura data are programmed in the non-volatile memory array 521. In some embodiments, the errors may be corrected using algorithms, including but not limited to, low-density parity-check (LDPC), cyclic codes, Hamming codes, etc.

Because pixels of a display device are arranged in an array including rows and columns, the luminance/mura data for the pixels of the display device may be stored in a non-volatile memory array (e.g., 321, 421, and 521) in a similar fashion. In some embodiments, the non-volatile memory array that stores the luminance/mura data for the pixels of the display device is accessed sequentially during read and write operations. In some embodiments, a non-volatile memory array may be partitioned into a plurality of memory banks to store the luminance/mura data such that a luminance adjusting circuit can obtain in parallel a set of luminance data from the plurality of memory banks and output in series pixel data corresponding to the set of data.

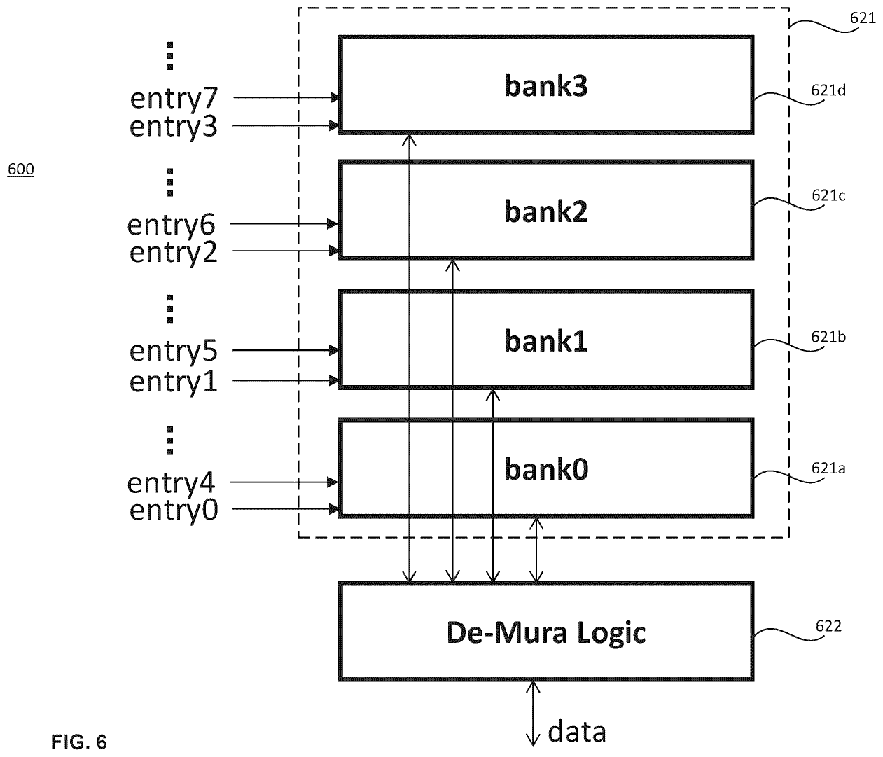

FIG. 6 is a block diagram illustrating another display control device 600 for controlling luminance of a display device according to an example embodiment. The display control device 600 includes a non-volatile memory array 621 and a de-mura logic 622 for providing mura correction for a display device. The non-volatile memory array 621 is partitioned into four memory banks 621a (bank0), 621b (bank1), 621c (bank2), and 621d (bank3). It should be understood that the non-volatile memory array 621 may be partitioned into more or fewer than four memory banks. For example, data entries 0-7 are luminance/mura data for pixels 1-8 located in a row of a display device. The data entries 0 and 4 (for pixels 1 and 5) are stored in memory bank 621a; the data entries 1 and 5 (for pixels 2 and 6) are stored in memory bank 621b; the data entries 2 and 6 (for pixels 3 and 7) are stored in memory bank 621c; and the data entries 3 and 7 (for pixels 4 and 8) are stored in memory bank 621d. During write operations, entries 0-3 may be written in parallel or in series into the memory banks 621a-621d. That is, four luminance data entries may be written in parallel or in series into four memory banks. In the next write operation, entries 4-7 may be written in parallel or in series into the memory banks 621a-621d.

During read operations, the de-mura logic 622 is configured to obtain data entries 0-3 in parallel from the memory banks 621a-621d and use the luminance data stored therein to calibrate image luminance data for pixels 1-4. The de-mura logic 622 then outputs the pixel luminance data in series for pixel 1-4. That is, the de-mura logic 622 is configured to read luminance data for mura correction from the memory banks in parallel and output pixel luminance data in series. The techniques allows accessing multiple luminance data entries in parallel at a slow speed and reading or writing data at a normal chip clock frequency to match the throughput need. In some embodiments, the techniques help to improve speed and/or design margins for a display control device.

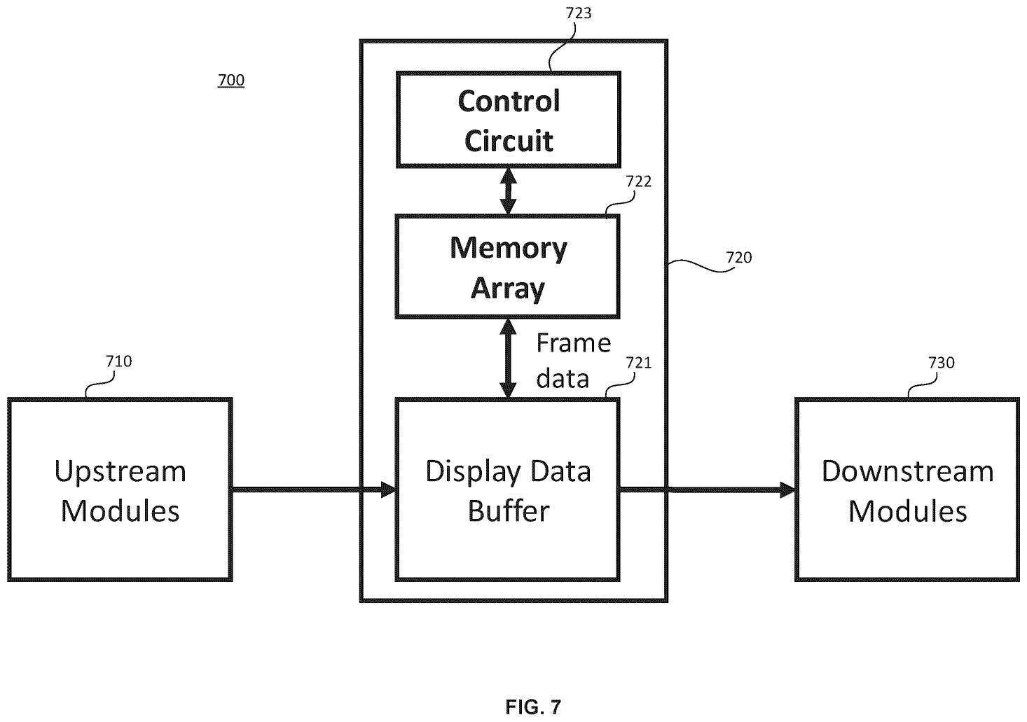

FIG. 7 is a block diagram illustrating another display control device 700 having a display data buffer device for controlling luminance of a display device according to an example embodiment. The display control device 700 includes one or more upstream modules 710, a display data buffer device 720, and one or more downstream modules 730. For example, the upstream modules 710 may include a digital signal compression encoder (e.g., encoder 104 in FIG. 2) coupled to an input interface (e.g., MIPI 102 in FIG. 2) and configured to encode the image data received from the input interface to generate encoded image data. The display data buffer device 720 is coupled to the digital signal compressing encoder and the input interface, and is configured to store the encoded image data and the image data. The downstream modules 730 may include a digital signal compression decoder (e.g., decoder 110 in FIG. 2) coupled to the display data buffer device 720 and configured to decode the encoded image data.

The display data buffer device 720 includes a display data buffer 721, a non-volatile memory array 722, and a control circuit 723 for controlling the non-volatile memory array 722. The display data buffer 721 may write frame data into and read frame data from the non-volatile memory array 722. For this purpose, the non-volatile memory array 722 is configured to be a multiple-time programmable memory device. In some embodiments, the non-volatile memory array 722 includes one of a resistive random access memory device, a phase-change random access memory device, a ferroelectric random access memory device, or a spin-transfer torque magnetic random access memory device.

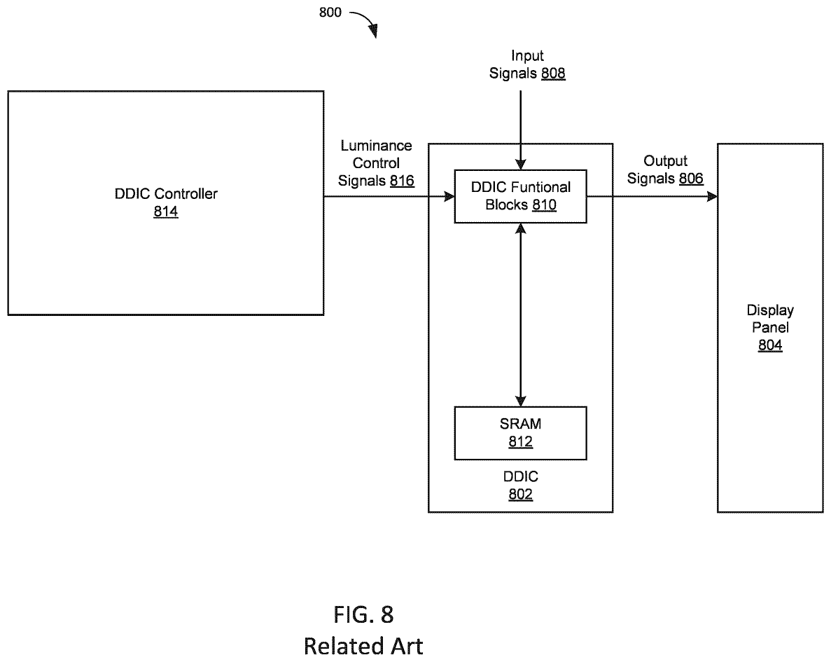

In some conventional systems such as the display driver system 100 of FIG. 1, the memory in the DDIC is generally implemented as SRAM, as discussed above. Such systems require only a single controller, which controls only the DDIC functional blocks. FIG. 8 is a block diagram illustrating a conventional display system 800 with a single controller according to an example embodiment. Referring to FIG. 8, the conventional display system 800 includes a DDIC 802 that includes DDIC functional blocks 810 and SRAM 812. The system 800 includes a DDIC controller 814 that generates luminance control signals 816.

The system 800 includes a DDIC 802 that generates output signals 806 to drive a display panel 804. The DDIC includes DDIC functional blocks 810. The DDIC functional blocks 810 may include one or more of the functional blocks of the conventional display driver system 100 of FIG. 1. The DDIC functional blocks 810 generate the output signals 806 based on input signals 808 in accordance with the luminance control signals 816 generated by the DDIC controller 814. The DDIC functional blocks 810 employ the SRAM 812.

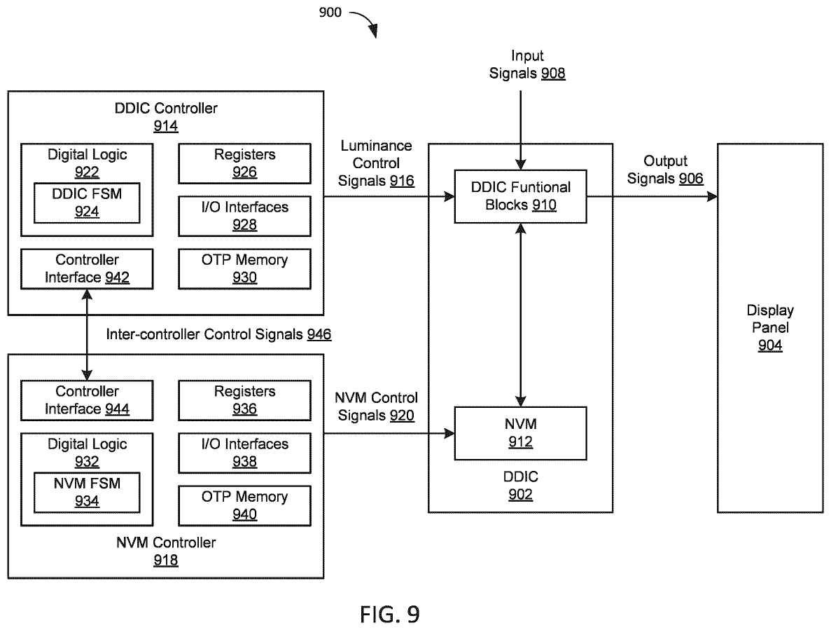

In some systems such as the display driver system 200 of FIG. 2, the memory in the DDIC is implemented as NVM, as discussed above. Such systems generally employ two controllers: a DDIC controller to control the DDIC functional blocks, and an NVM controller to control the NVM. FIG. 9 is a block diagram illustrating a display system 900 having two controllers according to an example embodiment. Referring to FIG. 9, the display system 900 includes a DDIC 902 that includes DDIC functional blocks 910 and NVM 912. The system 900 includes a DDIC controller 914 that generates luminance control signals 916, and an NVM controller 918 that generates NVM control signals 920.

The system 900 includes a DDIC 902 that generates output signals 906 to drive a display panel 904. The DDIC 902 includes DDIC functional blocks 910. The DDIC functional blocks 910 may include one or more of the functional blocks of the display driver system 200 of FIG. 2. The DDIC functional blocks 910 generate the output signals 906 based on input signals 908 in accordance with the luminance control signals 916 generated by the DDIC controller 914. The DDIC functional blocks 910 employ the NVM 912. The NVM 912 operates in accordance with the NVM control signals 920 generated by the NVM controller 918.

The DDIC controller 914 includes digital logic 922 that implements a finite state machine (FSM) 924. The FSM 924 determines the current work state of the DDIC 902 (e.g., power on, idle, data streaming, power off, etc.), and selects a specific set of logic functions to generate the luminance control signals 916 for other blocks under the current work state. The DDIC controller 914 also may include registers 926, I/O interfaces 928, and OTP memory 930. The DDIC controller 914 also may include a controller interface 942 to exchange inter-controller control signals 946 with the NVM controller 918.

The NVM controller 918 includes digital logic 932 that implements an FSM 934. The FSM 934 determines the current work state of the NVM block (e.g., initialization, write, read, etc.), and selects a specific set of logic functions to generate the NVM control signals 920 for other blocks under the current work state. The NVM controller 918 also may include registers 936, I/O interfaces 938, and OTP memory 940. The NVM controller 918 also may include a controller interface 944 to exchange the inter-controller control signals 946 with the DDIC controller 914.

Based on input signals and the data read from the registers, OTP memory and I/O interfaces, the state machines will also determine whether to switch to another state in the next clock cycle. Once the state is switched, the set of logic functions for control signal generation may also be switched. The various signals generated by the two controllers may include analog circuitry configuration signals, (e.g. voltage values, current values, etc.), clock signals for various blocks, which may also be used to synchronize the two controllers, selection signals for the memory arrays (e.g. wordline address, bitline address, etc.), and timing signals (e.g. pulse duration, pulse width, pulse counts, etc.).

The use of two controllers has some disadvantages. An additional controller is needed, namely NVM controller 918. Many parts are replicated, including registers 926, 936, I/O interfaces 928, 938, and OTP memories 930, 940. In addition, extra parts are required, such as controller interfaces 942, 944.

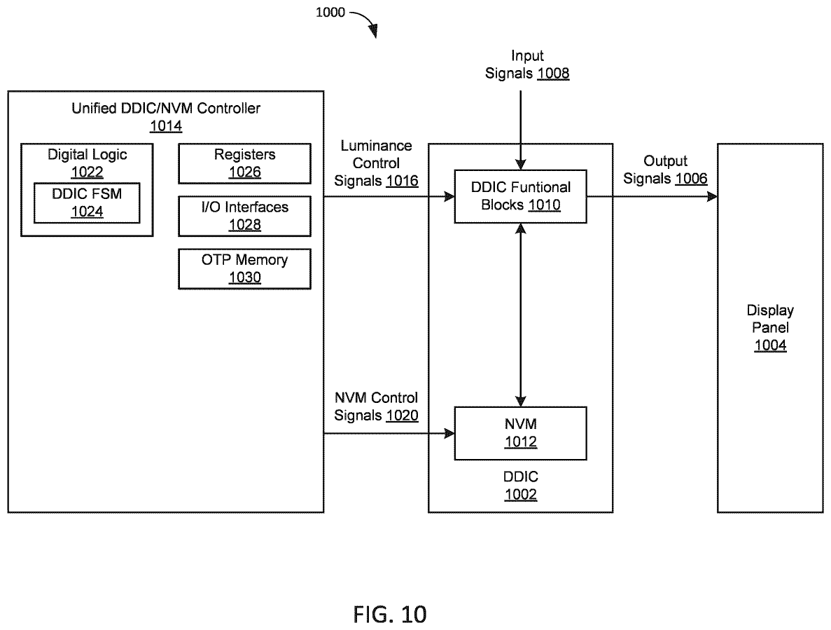

Some embodiments of the disclosed technologies provide improvements to these systems by providing a single unified controller for controlling both the DDIC functional blocks and the NVM. FIG. 10 is a block diagram illustrating a display system 1000 having a unified DDIC/NVM controller according to an example embodiment. Referring to FIG. 10, the display system 1000 includes a DDIC 1002 that includes DDIC functional blocks 1010 and NVM 1012. The system 1000 includes a unified DDIC/NVM controller 1014 that generates both the luminance control signals 1016 and the NVM control signals 1020.

The system 1000 includes a DDIC 1002 that generates output signals 1006 to drive a display panel 1004. The DDIC 1002 includes DDIC functional blocks 1010. The DDIC functional blocks 1010 may include one or more of the functional blocks of the display driver system 200 of FIG. 2. The DDIC functional blocks 1010 generate the output signals 1006 based on input signals 1008 in accordance with the luminance control signals 1016 generated by the unified DDIC/NVM controller 1014. The DDIC functional blocks 1010 employ the NVM 1012. The NVM 1012 operates in accordance with the NVM control signals 1020 generated by the unified DDIC/NVM controller 1014.

The unified DDIC/NVM controller 1014 includes digital logic 1022 that implements a finite state machine (FSM) 1024. The FSM 1024 determines the current work state of the DDIC 1002 (e.g., power on, idle, data streaming, power off, etc.), and selects a specific set of logic functions to generate the luminance control signals 1016 for other blocks under the current work state. The FSM 1024 also determines the current work state of the NVM block (e.g., initialization, write, read, etc.), and selects a specific set of logic functions to generate the NVM control signals 1020 for other blocks under the current work state. The unified DDIC/NVM controller 1014 also may include registers 1026, I/O interfaces 1028, and OTP memory 1030.

The display system 1000 of FIG. 10 provides several advantages over the display system 900 of FIG. 9. The display system 1000 of FIG. 10 requires only a single controller, namely unified DDIC/NVM controller 1014, in comparison with the multiple controllers of the display system 900 of FIG. 9. Therefore, only one state machine is needed. All control signals are generated together by that state machine. Furthermore, no parts are replicated. The benefits of this approach include smaller area, lower cost, and faster control.

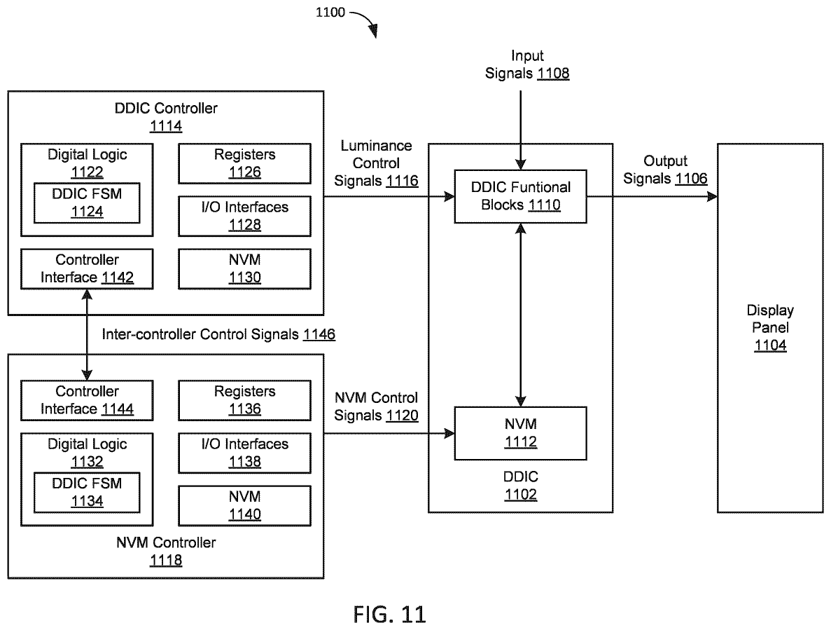

In some dual-controller systems such as the display driver system 900 of FIG. 9, the memories in the controllers are implemented as OTP memory, as discussed above. In some embodiments, the OTP memories in one or both controllers are replaced with NVM. FIG. 11 is a block diagram illustrating a display system 1100 having two controllers with NVM according to an example embodiment. Referring to FIG. 11, the memories in both the DDIC controller 1114 and the NVM controller 1118 have been replaced with NVM 1130 and NVM 1140, respectively. For example, the NVM may be resistive random-access memory (RRAM), phase-change memory (PCM), ferroelectric RAM (FeRAM), magnetoresistive RAM (MRAM), or spin-transfer torque RAM (STRAM). The NVM 1130 in the DDIC controller 1114 may be controlled by the DDIC FSM 1124 or other logic. The NVM 1140 in the NVM controller 1118 may be controlled by the NVM FSM 1134 or other logic. Other components of the display system 1100 of FIG. 11 may be as described for corresponding components of the system 900 of FIG. 9. The use of NVM instead of OTP memory results in a more cost-effective solution, with lower cost, lower operating power. In addition, the NVM can be reprogrammed if desired. Furthermore, memory control logic is simplified as all memory blocks can be controlled in the same way.

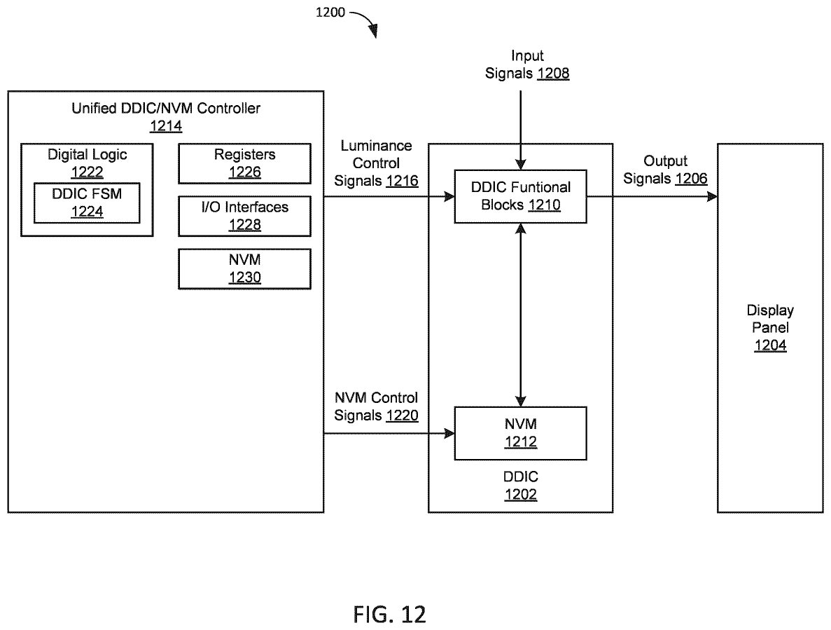

In some embodiments having a unified DDIC/NVM controller, the OTP memory in the unified DDIC/NVM controller is replaced with NVM. FIG. 12 is a block diagram illustrating a display system 1200 having a unified DDIC/NVM controller with NVM according to an example embodiment. Referring to FIG. 12, the OTP memory in the unified DDIC/NVM controller 1214 has been replaced with NVM 1230. For example, the NVM may be RRAM, PCM, FeRAM, MRAM, or STRAM. The NVM 1230 in the unified DDIC/NVM controller 1214 may be controlled by the DDIC FSM 1224 or other logic. Other components of the display system 1200 of FIG. 12 may be as described for corresponding components of the system 1000 of FIG. 10. The use of NVM instead of OTP memory results in a more cost-effective solution, with lower cost, lower operating power. In addition, the NVM can be reprogrammed if desired. Furthermore, memory control logic is simplified as all memory blocks can be controlled in the same way.

### Embodiment 1: Incorporating Embedded Non-Volatile Memory (NVM) for Display Adjustment in Head-Mounted Display (HMD) Driver Circuits

Head-mounted displays (HMDs) pose distinct challenges in display driver design, primarily due to their proximity to the user's eyes and the resulting demand for exceptional visual clarity. Unlike standard display devices, HMDs require significantly higher pixel density to avoid the “screen-door effect,” where individual pixels become visible, disrupting the immersive experience. As a result, achieving clear and vivid visuals necessitates real-time pixel-wise corrections for brightness and color, making the use of sophisticated algorithms for adjusting luminance and other display parameters crucial.

In HMD systems, not only does the display driver IC need to manage high pixels-per-inch (PPI) for enhanced resolution, but it must also manage the increased variation in pixel characteristics that result from integrating more light-emission devices within a confined area. These variations, if left unchecked, can lead to non-uniform brightness, color distortion, and other visual artifacts. To address these issues, HMD driver circuits require advanced correction algorithms that go beyond typical display adjustments, incorporating sub-pixel rendering correction, as well as geometry correction techniques like fringe, foveation, and wobulation adjustments. This ensures a uniform and immersive visual experience, despite the unique physical requirements of HMDs.

In the conventional approach described in FIG. 1, mura correction (demura) has been handled by loading luminance correction data from external NOR Flash into internal SRAM during the power-on sequence, after which the data is used for real-time pixel adjustments. However, this approach comes with significant drawbacks, particularly for HMDs. The use of external NOR Flash increases the complexity of the circuitry and consumes more power, which is problematic for portable, battery-powered devices like HMDs. Additionally, SRAM is costly in terms of chip area and power consumption, both of which are critical concerns in mobile applications.

To overcome these limitations, the use of embedded non-volatile memory (NVM) offers a more efficient solution. By integrating NVM directly into the display driver IC, real-time access to pre-programmed mura correction data becomes possible without the need for external memory components.

More importantly, the role of NVM in HMD driver circuits may extend beyond just mura correction. Due to the high visual demands of HMDs, additional adjustments are necessary to ensure optimal display quality. For instance, NVM may be used for storing data related to advanced corrections such as sub-pixel rendering, fringe adjustment, foveation, wobulation, and so on. These adjustments are essential for addressing the unique visual requirements of HMDs, which are far more complex than those of typical display devices.

Sub-pixel rendering enhances the display's resolution by manipulating individual RGB sub-pixels to sharpen image quality. Fringe adjustment ensures that image data aligns correctly with the display's physical edges, which is critical for HMDs with non-standard screen shapes. Foveation enables efficient rendering by focusing high-resolution details where the user is looking, reducing processing power for peripheral vision areas, while wobulation improves perceived resolution by shifting image data slightly to fill gaps between pixels.

Incorporating this additional correction data directly into the NVM allows HMD systems to perform these complex adjustments in real time, significantly enhancing the user experience by ensuring clear, consistent, and immersive visuals. This approach reduces both chip area and power consumption, while enabling high-performance, real-time display adjustments specifically designed to meet the demanding visual requirements of HMD systems.

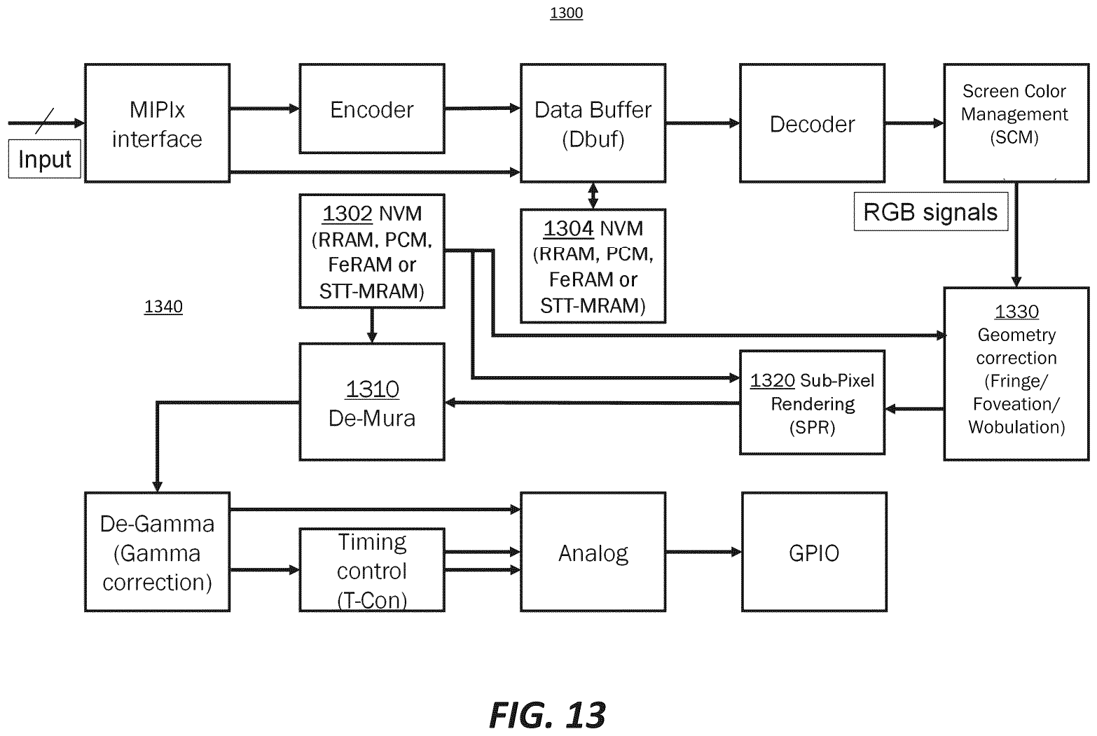

FIG. 13 illustrates a block diagram of a display driver system 1300 embedded with NVM for HMDs, according to an example embodiment. The block diagram is similar to the block diagram illustrated in FIG. 2, with specific enhancement designed for HMDs.

In some embodiments, the display driver system 1300 may be controlled by a controller to adjust the rendering of image data on an HMD (i.e., the display of the HMD). The image data to be rendered on the HMD may be received from a host device.

As shown in FIG. 13, the display driver system 1300 may replace traditional RAM with a non-volatile memory array (NVM) 1302. The NVM 1302 may be implemented using RRAM, PCM, FeRAM, or STT-MRAM technologies. In some embodiments, the NVM 1302 is a one-time programmable memory, meaning it can only be written with data once. In other embodiments, the NVM 1302 may be a multi-time programmable memory that can be reprogrammed multiple times.

In some embodiments, the NVM 1302 may consist of a plurality of memory cells programmed to store both luminance correction data and geometry correction data for the HMD display. If the NVM 1302 is a multi-time programmable memory, these correction data may be periodically updated and reprogrammed as needed.

In some embodiments, the NVM 1302 may further include a serial or parallel interface directly coupled to multiple functional circuits in the display driver system 1300, such as a de-mura circuit 1310, a sub-pixel rendering (SPR) circuit 1320, and a geometry correction circuit 1330. In some embodiments, the multiple functional circuits may directly access the corresponding correction data from the NVM 1302. Storing these correction data in the NVM 1302 allows for quick and efficient real-time display adjustments, crucial for the high visual clarity that HMDs demand.

In some embodiments, the correction data stored in the NVM 1302 may include luminance correction data. The luminance correction data may include pixel-wise brightness correction data and/or pixel-wise color correction data. The pixel-wise brightness correction data may be used to ensure consistent luminance across the display, maintaining uniform brightness and preventing any localized brightness anomalies. Similarly, the pixel-wise color correction data may be used to ensure accurate color representation. Deviations in the color output of individual pixels can be corrected using the data stored in NVM, maintaining uniform and accurate color reproduction across the entire display. As shown in FIG. 13, the luminance correction data may be directly accessed by the de-mura circuit 1310 to calibrate the luminance data across the screen and use the data to calculate individual correction to each pixel, in order to achieve more uniform luminance/appearance of the HMD display.

In some embodiments, the correction data stored in the NVM 1302 may include sub-pixel rendering data to enhance the resolution of the HMD display by controlling each subpixel (red, green, and blue elements). This sub-pixel rendering technique increases the apparent resolution by treating each RGB sub-pixel as an individual unit. As shown in FIG. 13, the sub-pixel rendering correction data may be accessed by the sub-pixel rendering (SPR) circuit 1320 to perform the sub-pixel rendering correction, thereby improving the image sharpness and clarity without increasing the pixel density of the HMD display.

In some embodiments, the correction data stored in the NVM 1302 may include geometry correction data. The geometry correction data may include shape information of the HMD for Fringe adjustment, Foveation correction data for foveated display, and Wobulation correction data for wobulated display. As shown in FIG. 13, the geometry correction data may be directly accessed by the geometry correction circuit 1330 to perform geometry correction on the HMD, which may include fringe adjustment, forveated display, and wobulation.

For instance, fringe adjustment addresses the spatial geometry of images, particularly for displays with irregular shapes (e.g., smartphones with notches, bezels, or curved edges). It adjusts pixel data at the edges of the display so that images are correctly aligned and fit within the physical shape of the screen. The fringe adjustment may be performed by the geometry correction circuit 1330 based on the shape information of the HMD display device, such that pixel data at edges of the image data are adjusted to align and fit within the HMD display device.

As another example, the human eye has the highest visual acuity in the fovea, the small central region of the retina. Foveated displays, based on foveation correction data, prioritize rendering high-resolution images in the foveal area (the center of the user's gaze) while rendering lower resolution in peripheral areas, where visual sensitivity is lower. In HMDs, such as virtual reality (VR) or augmented reality (AR) systems, this approach is particularly beneficial as it reduces the computational power and bandwidth needed to render high-resolution images across the entire field of view. Storing foveation correction data in NVM 1302 for direct, real-time access is crucial in HMDs, where maintaining real-time high frame rates and resolution is essential for user immersion and comfort, while also managing power consumption and processing demands.

As yet another example, wobulation helps improve perceived image quality without the need for increasing pixel density, which is physically challenging in small, close proximity displays such as HMDs. Using wobulation correction data, the geometry correction circuit 1330 can shift (wobble) the image data in succession to increase the effective resolution of the image data on the HMD. This technique creates the perception of a higher resolution than the native resolution of the HMD panel. The wobulation creates a perception of higher resolution than a native resolution of the HMD panel.

In some embodiments, the NVM 1302 may further include pixel-wise correction data for varifocal display and/or multi-focal display. These correction data may allow the display driver system 1300 to dynamically adjust focal planes based on the user's viewing distance or focus. In varifocal displays, the display driver system 1300 can adjust the focal length in real time, ensuring that the rendered images remain sharp and in focus as the user's gaze shifts between near and far objects. Similarly, in multi-focal displays, multiple focal planes can be rendered simultaneously, allowing for a more natural depth of field and reducing eye strain. Storing these correction data in NVM 1302 allows for quick, real-time adjustments, enhancing the overall visual experience and providing a more immersive and comfortable viewing experience in HMDs.

In some embodiments, the display driver system 1300 may further include a second NVM device 1304 coupled to the data buffer in the display driver system 1300. The second NVM device 1304 may be implemented in a similar way as the NVM device 1302 but configured to replace the SRAM 108 illustrated in FIG. 1.

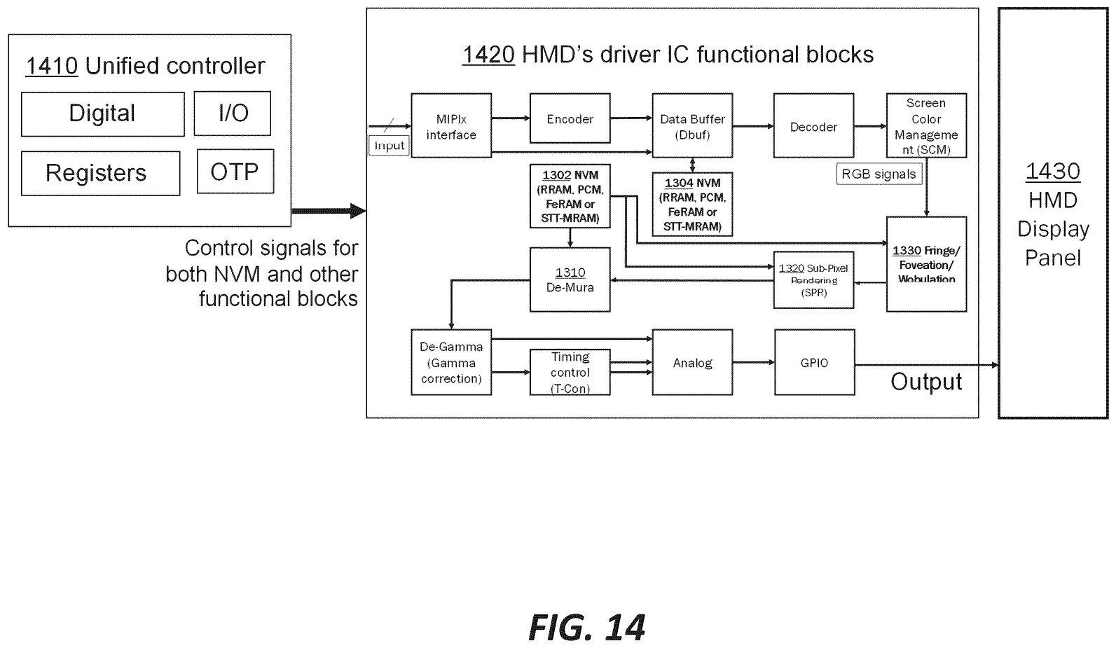

FIG. 14 illustrates the architecture of a display driver system 1420 embedded with Non-Volatile Memory (NVM), controlled by a unified controller 1410, according to an example embodiment. The display driver system 1420 maps to the system 1300 described in FIG. 13, which highlights the use of NVM for handling a variety of display corrections in HMDs. The unified controller 1410 operates in a manner similar to the unified controller 1014 described in FIG. 10, offering key advantages such as reduced physical footprint, lower production cost, and faster control signals, which are critical in the compact and power-sensitive environment of HMD devices.

In this embodiment, the unified controller 1410 manages and feeds control signals to both the NVM 1410 and the functional circuits within the display driver system 1420. The NVM 1410 stores essential correction data for improving image quality in HMDs, such as mura correction data, sub-pixel rendering data, and advanced geometry correction data (e.g., for fringe adjustment, foveation, and wobulation). These corrections ensure that the display presents high visual clarity and performance in real time, addressing the specific needs of HMD systems, including the close proximity of the display to the user's eyes and the requirement for high pixel density.

The unified controller 1410 streamlines the management of the display driver system by coordinating all necessary control signals for both the NVM 1410 and the functional display circuits, such as the de-mura circuit 1310, the sub-pixel rendering circuit 1320, and the geometry correction circuit 1330. This ensures that the various types of correction data—whether for brightness, color, focus adjustments (in the case of varifocal or multi-focal displays), or geometric corrections—are accessed and applied in real-time to adjust the image displayed on the HMD panel.

By centralizing the control operations, the unified controller 1410 optimizes the speed and efficiency of the system, minimizing latency in accessing and applying correction data. This is particularly important in HMDs where real-time performance, high frame rates, and quick response to user movements are essential for delivering a seamless and immersive experience.

The display driver system 1420 receives the control signals from the unified controller 1410 and processes the image data accordingly, applying the necessary corrections stored in the NVM 1410. The system then outputs display signals to the HMD display panel 1430, ensuring that the corrected image data is rendered with high precision and quality. This real-time correction enhances the user's viewing experience, addressing issues like mura, screen-door effect, and focus-related discrepancies, and providing sharper, more vibrant images with optimized geometry and resolution.

### Embodiment 2: Incorporating Non-Volatile Memory (NVM) for OLED Aging and Deburn-in Correction in Display Driver Systems

OLED displays, while renowned for their vibrant color reproduction and high contrast, suffer from degradation over time due to the accumulation of defects in the emissive zone of the pixels. This degradation, often referred to as OLED aging, results in a reduction of luminous efficiency, causing affected pixels to appear darker under the same input conditions. More critically, uneven degradation of OLED pixels—commonly referred to as burn-in—can occur after prolonged usage, leading to visual artifacts such as residual images and discoloration. To address this, deburn-in techniques have been developed to restore uniformity to the display by correcting the effects of aging and mitigating burn-in.

Traditionally, deburn-in correction data has been stored in volatile memory such as SRAM within the display driver system. However, this approach has limitations, particularly in terms of power consumption and system complexity. SRAM requires power to retain data, meaning that deburn-in data must be reloaded or recalculated upon every power cycle. Additionally, SRAM occupies significant chip area, and its integration alongside other display correction functions (such as demura and foveation) results in higher system cost and increased power draw, which is a critical concern in portable devices like head-mounted displays (HMDs).

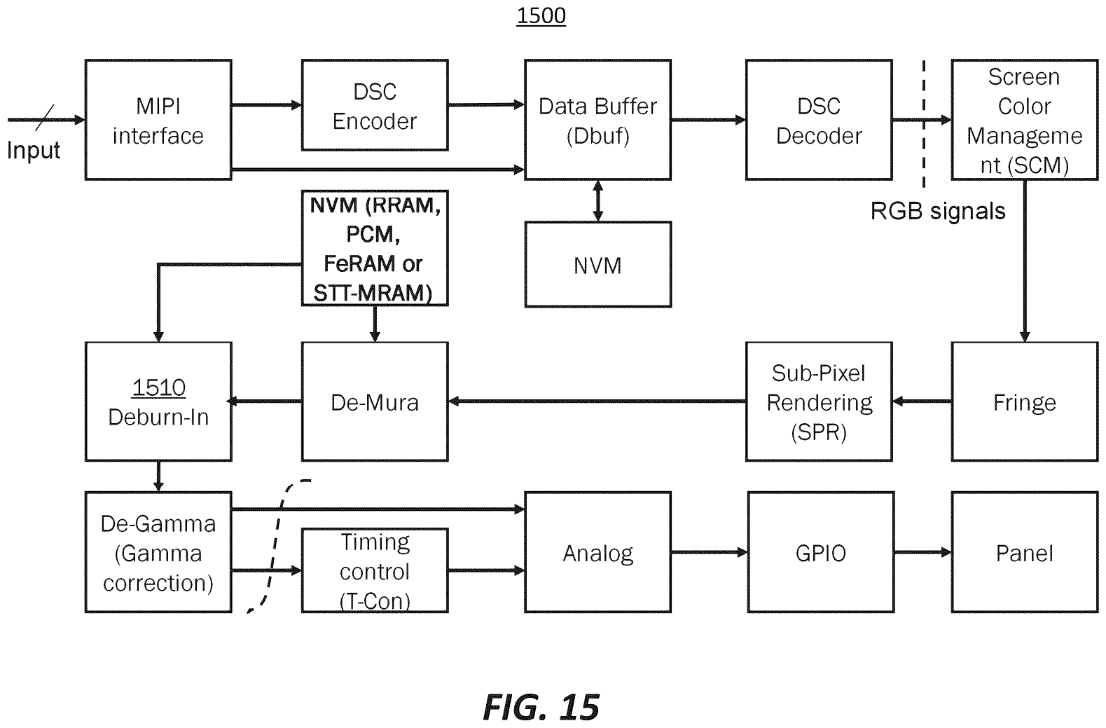

FIG. 15 illustrates an example display driver system 1500 using embedded NVM to store deburn-in correction data, offering several technical improvements over traditional SRAM-based solutions. By utilizing NVM, the deburn-in circuit 1510 within the display driver system 1500 can access pre-stored correction data directly, without the need for reloading upon every system startup. This not only reduces system initialization time but also eliminates the power overhead required by SRAM to retain data, resulting in a more energy-efficient solution—an essential feature for battery-powered devices.

The stored deburn-in correction data can include parameters related to the aging of each pixel, collected through periodic testing of the screen's appearance after prolonged usage. These parameters, similar to demura data, help the display driver system 1500 assess the degradation of each pixel and correct its output to maintain uniform luminance and color accuracy across the display. This real-time access to aging data allows the deburn-in circuit 1510 to dynamically adjust pixel output to compensate for any darkening or discoloration, ensuring a more uniform visual experience over time.

For example, if a particular pixel has experienced a reduction in luminous efficiency, the deburn-in circuit may increase the drive current to that pixel to compensate for the loss in brightness. Similarly, if the degradation has caused a shift in the color output (e.g., a blue pixel appearing more green due to decreased blue emission), the circuit can apply differential control voltages to red, green, and blue subpixels to restore the intended color balance. This adjustment involves a lookup operation where the deburn-in correction data is used to index a compensation table stored in the NVM. The compensation table provides parameters, such as gamma correction values or drive strength adjustments, that are applied to each pixel in real-time during display refresh. This approach allows the display driver to fine-tune pixel performance dynamically, ensuring uniform brightness and color accuracy across the display.

In some embodiments, the display driver system 1500 may store estimated pixel lifetimes in the NVM. This data, generated through analysis of the screen's appearance and usage patterns, allows the deburn-in circuit 1510 to predict the relative lifespan of each pixel and proactively apply stress to underused pixels to even out degradation across the display (a process sometimes referred to as reverse burn-in). For example, stress may be applied to underused pixels during idle periods of the OLED display, the stress being applied by increasing the drive current or maintaining the pixels in an active state for a prolonged duration to accelerate aging of the underused pixels. By stressing less-used pixels to reach a more uniform degradation level, the system can prevent significant differences in aging between pixels, further extending the overall life of the display.

By leveraging NVM for these correction data, the display driver system 1500 also offers greater flexibility in terms of multi-time programmability. Unlike SRAM, where data is lost on power-off and must be reloaded from external sources, NVM can retain correction data even when the device is powered down, and it can be periodically reprogrammed as new aging data is collected. This simplifies the system design by eliminating the need for external memory components and reducing the complexity of the deburn-in process.

### Embodiment 3: Display Driver System with Always-On-Display (AOD) Information Stored in Embedded NVM

The above-described NVM-based architecture can also be used in the Always-On Display (AOD) scenarios, enhancing the efficiency and flexibility of AOD by providing a more power-efficient alternative to the traditional RAM-based architecture. AOD is widely used in smartphones to display essential information such as time, date, battery status, and notifications while the device is in sleep mode. The primary limitation of conventional AOD implementations, which rely on RAM, is their continuous power consumption. Since RAM is a volatile memory, it requires a constant supply of power to maintain the displayed content. This need for persistent energy draws on the battery and limits the potential for optimizing power usage in devices equipped with AOD.

By introducing NVM into a display driver chip for AOD use cases, a more sustainable approach can be achieved. NVM, unlike RAM, retains data without the need for continuous power, making it an ideal solution for applications like AOD where static information is displayed for extended periods. Replacing the traditional RAM-based memory with NVM allows for a reduction in power consumption, as the display content can be stored and accessed from memory that does not require frequent refresh cycles. This capability not only prolongs battery life but also ensures that AOD displays can remain active without the significant power draw typically associated with maintaining volatile memory.

In addition to the energy-saving benefits, using NVM for AOD enables reprogramming of the display content based on dynamic user preferences or changing environmental conditions. NVM can store different AOD configurations, including customized layouts, color schemes, or information preferences, and update them seamlessly without requiring the device to constantly access the processor or RAM.

One feature of the proposed AOD system is that it can selectively activate only a subset of the pixels on the screen, further optimizing power consumption. In typical AOD implementations, it is not necessary to light up the entire display since only specific information like the time, date, or a few notification icons need to be visible. By using NVM to store the AOD content and selectively driving only a small number of pixels corresponding to the required information, the system can significantly reduce the power required for maintaining the display. This selective pixel activation allows for the display of essential information while keeping the majority of the screen turned off, thus minimizing energy usage and extending battery life. Such an approach leverages the power-efficient characteristics of NVM along with intelligent pixel management to create a highly efficient AOD system that only utilizes the necessary display areas, rather than the full screen, when the device is in sleep mode.

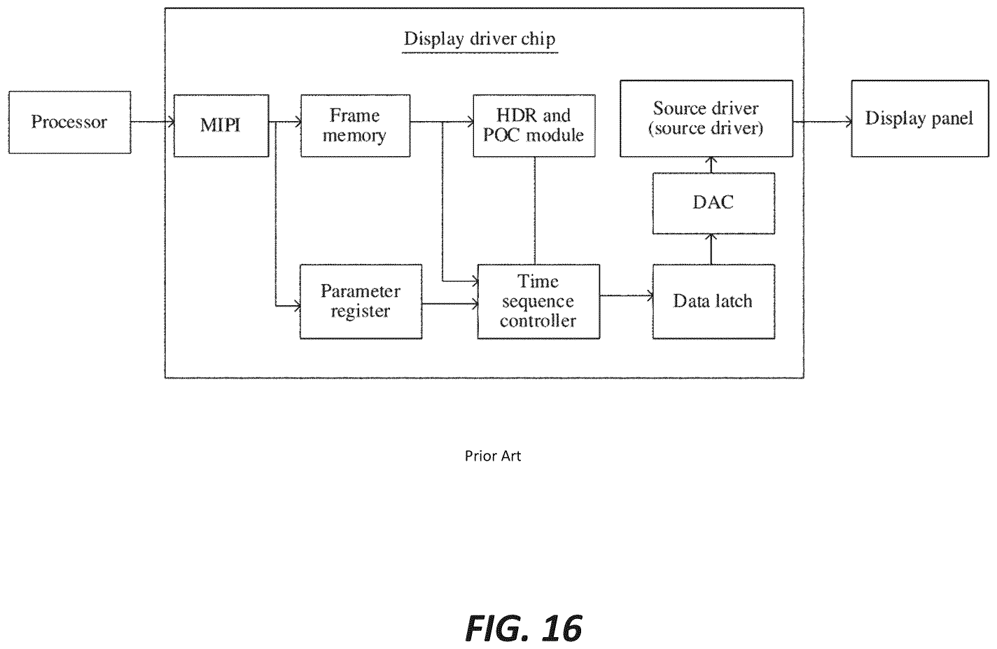

FIG. 16 illustrates a schematic structural diagram of a conventional display driver chip for AOD. The display driver chip consists of a mobile industry processor interface (MIPI) display serial interface (DSI), a frame memory, a parameter register, a high dynamic range (HDR) and programmable optical compensation (POC) module, a time sequence controller, a data latch, a digital-to-analog converter (DAC), and a source driver.

The MIPI DSI is responsible for receiving data from the processor, sending display data to the frame memory, and transmitting configuration parameters (such as power sequences, brightness levels, and control parameters) to the parameter register. These control parameters regulate the connectivity between the frame memory and the HDR and POC module or between the frame memory and the time sequence controller. For example, when the control parameter is set to 1, the frame memory connects to the HDR and POC module and disconnects from the time sequence controller. Conversely, when the control parameter is 0, the frame memory disconnects from the HDR and POC module and connects to the time sequence controller. This control parameter is determined by the processor, based on the AOD mode intelligently selected by the terminal. If the terminal selects the second mode, the control parameter directs the frame memory to connect to the HDR and POC module while disconnecting from the time sequence controller. If the first mode is selected, the control parameter causes the frame memory to disconnect from the HDR and POC module and connect to the time sequence controller.

The frame memory functions by receiving data from the MIPI DSI. If connected to the HDR and POC module and disconnected from the time sequence controller, the frame memory sends the data to the HDR and POC module. If disconnected from the HDR and POC module and connected to the time sequence controller, it sends the data to the time sequence controller.

The HDR and POC module processes the received data for display effects such as contrast and uniformity adjustments before sending it to the time sequence controller.

The parameter register, after receiving the configuration and control parameters from the MIPI DSI, forwards the configuration parameters to the time sequence controller. It also manages the connectivity between the frame memory and either the HDR and POC module or the time sequence controller, depending on the control parameter.

The time sequence controller processes the data from either the frame memory or the HDR and POC module, adjusting it according to the configuration parameters and display effects required for the display panel. It then sends the processed data to the data latch.

The data latch, upon receiving the processed data from the time sequence controller, passes it to the DAC. The DAC converts the digital data into an analog signal and sends it to the source driver.

Finally, the source driver triggers the display panel by using the analog signal to display the processed data.

Note that the parameter register controls the connectivity between the frame memory and the HDR and POC module, as well as between the frame memory and the time sequence controller, by managing the connectivity status of switches between these components. These switches could be transistors or other forms of switches, and the exact implementation is not restricted to a particular type.

An example AOD process using the conventional display driver chip may begin when an electronic device receives a screen-off operation. This operation can be triggered by a user pressing the power key, tapping a virtual button on the touchscreen, using a predefined gesture (such as a multi-finger swipe), or performing a long press on a specific control.

Once the screen-off operation is initiated, the electronic device collects device status information, which relates to the device's current operating state. This information is compiled from various sensors and inputs. For example, the device may use an ambient light sensor to gauge light intensity, an accelerometer to detect the direction and value of gravity, or other sensors to measure temperature, humidity, and the user's heart rate. The device can also gather information such as geographical location via GPS, alarms set by the user, remaining battery power, or the frequency of screen-on/off events. Additionally, configuration settings set by the user on an always-on display control screen may also be part of the device status information.

Based on this gathered information, the electronic device automatically determines which AOD mode to use. The device analyzes the data using its processor or AI chip and selects between two predefined modes: a first, simpler mode or a second, more complex multicolor mode. For example, if the accelerometer detects that the user is walking, it might infer the user is on the way home, and if the time is after work hours, it could determine that the AOD mode should be set to multicolor mode for a more vibrant display. Conversely, if the battery is below 10%, the device may automatically choose the simpler AOD mode to conserve power.

After determining the appropriate AOD mode, the device then displays the corresponding AOD interface when the screen is turned off. The AOD interface can present a range of information, such as the time, date, notifications, or other user-defined content. Depending on the mode, the display could show monochromatic data to save power or a full-color display with enhanced information.

In some cases, the electronic device may adjust the display effects based on additional inputs or user preferences. For instance, a user might have selected a specific display effect from a list of options in the device's settings. The AOD interface may also be customized to show a different number of application icons depending on the device's battery level. If the battery is at 80% or higher, for example, eight application icons could be displayed, while lower battery levels would result in fewer icons being shown.

Moreover, the electronic device can respond to a screen-on operation from the user, such as pressing the power button or another designated action. When this occurs, the lock screen replaces the AOD interface.

The device status information may also include settings pre-configured by the user, such as preferred AOD modes or other custom settings like alarms and screen-on/off frequencies. This information helps the device intelligently switch between different display modes based on the user's needs and the current operational state of the device.

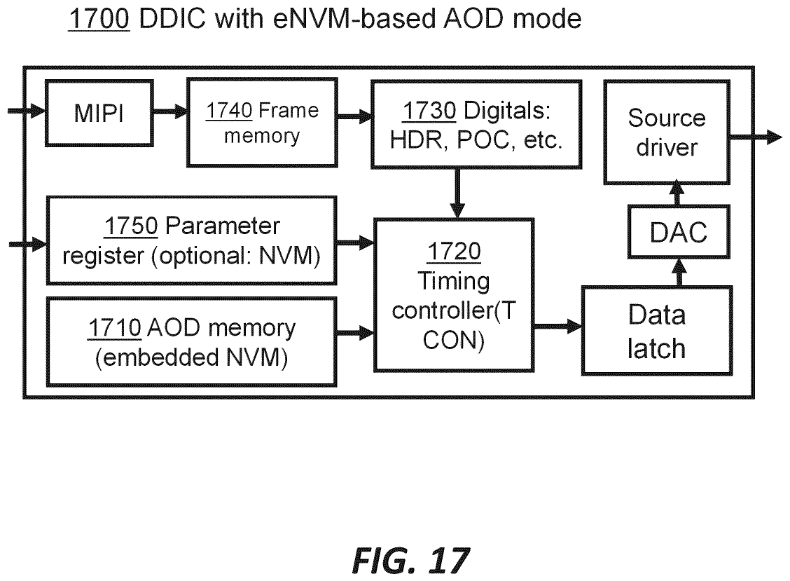

FIG. 17 illustrates a schematic structural diagram of an NVM-based display driver integrated circuits (DDIC) 1700 for AOD, according to an example embodiment.

The NVM-based DDIC 1700 introduces several significant improvements over the conventional design illustrated in FIG. 16, particularly in how it handles memory storage, power consumption, and data processing. In the conventional AOD driver chip in FIG. 16, the information displayed during the AOD mode is stored either in frame memory or, in some cases, directly sent from the processor in a Ramless system. This frame memory is also responsible for storing regular display information, which requires additional processing such as contrast and uniformity enhancements through HDR and POC modules. The time sequence controller in FIG. 16 receives both the AOD display information and the regular display data from the frame memory, making no distinction in the memory management between these two types of display modes.

In the new NVM-based DDIC 1700, the AOD-related display information is primarily stored in a dedicated AOD NVM 1710, rather than being stored in the frame memory 1740. This separation improves the overall efficiency of memory management by offloading AOD data from the frame memory 1740, particularly important in low-power modes. Since NVM 1710 can retain data without the need for constant power, it dramatically reduces power consumption during AOD mode, which is a critical feature for always-on displays. Unlike volatile frame memory that requires continuous power to maintain data, NVM's non-volatile nature enables the DDIC 1700 to store and display AOD information without ongoing power usage.

Another key improvement in the DDIC 1700 is the introduction of an input switching mechanism that directs display information to the time sequence controller 1720 based on whether the system is in AOD mode or regular display mode. In AOD mode, the time sequence controller 1720 receives its input directly from the AOD NVM 1710, bypassing the more complex HDR and POC modules 1730 that are required for processing regular display data. This switch ensures that the AOD information, which is generally simpler and static, is handled more efficiently without invoking unnecessary processing resources. During regular, non-AOD mode, the input switches back to the traditional digital data flow through HDR and POC modules 1730 to apply necessary enhancements like contrast and uniformity adjustments. This dynamic input switching optimizes the data flow for both modes, further improving efficiency.

In some embodiments, the parameter register in the conventional DDIC in FIG. 16 may NVM to store configuration parameters, such as the power sequence for turning the screen on or off, brightness settings, and control parameters related to the display panel during operation. The control parameter manages the connectivity between the frame memory and the HDR and POC module 1730, as well as between the frame memory 1740 and the time sequence controller 1720.

For instance, when the control parameter is set to 1 (corresponding to AOD), the time sequence controller 1720 connects to AOD NVM 1710 and disconnects from the HDR and POC module 1730. Conversely, when the control parameter is set to 0 (corresponding to non-AOD), the time sequence controller 1720 disconnects AOD NVM 1710 and connects to the HDR and POC module 1730. The value of the control parameter is determined by a processor, based on the always-on display mode selected by the terminal.

As another example, when the DDIC 1700 receives an instruction to enter AOD mode, the NVM-based DDIC retrieves the relevant AOD information stored in NVM. This information may include essential display parameters such as the time, date, notifications, and other simple visuals required for the low-power AOD interface. The system then determines the appropriate AOD interface based on the device's current status, such as battery level or user settings, and displays the corresponding interface on the screen. Since NVM retains data without the need for constant power, it significantly reduces energy consumption while maintaining the AOD interface.

When the device receives an instruction to exit AOD mode (e.g., upon user interaction or a command to return to full display mode), the DDIC 1700 switches back to frame memory 1740 (RAM) to retrieve the more complex image data required for regular display operation. The image data being fed into HDR and POC module 1730 for processing and generating the appropriate non-AOD display interface, which may include dynamic graphics, applications, and more detailed information. The non-AOD display interface is then rendered on the screen.

The following table highlights the difference between the conventional DDIC in FIG. 16 and the NVM-based DDIC 1700 in FIG. 17.

| Aspect | Conventional DDIC in FIG. 16 | NVM-Based DDIC 1700 in FIG. 17 |
|---|---|---|
| AOD Data Storage | In frame memory or sent from | Stored in dedicated AOD NVM. |
| | processor. | |
| Time Sequence | Receives all display data from | Switches between HDR/POC and |
| Controller Input | frame memory. | AOD NVM based on display mode. |
| Power Consumption | Higher due to continuous | Lower, thanks to NVM which retains |
| | refreshing of volatile memory. | data without power. |
| Display Processing | All data (AOD and non-AOD) | AOD data bypasses HDR/POC |
| | passes through HDR/POC. | modules, reducing processing needs. |
| System Flexibility | Limited separation of data | Distinct handling of AOD and non- |
| | handling. | AOD data, improving efficiency. |

### Embodiment 4: Touch and Display Driver Integration System with Embedded Non-Volatile Memory

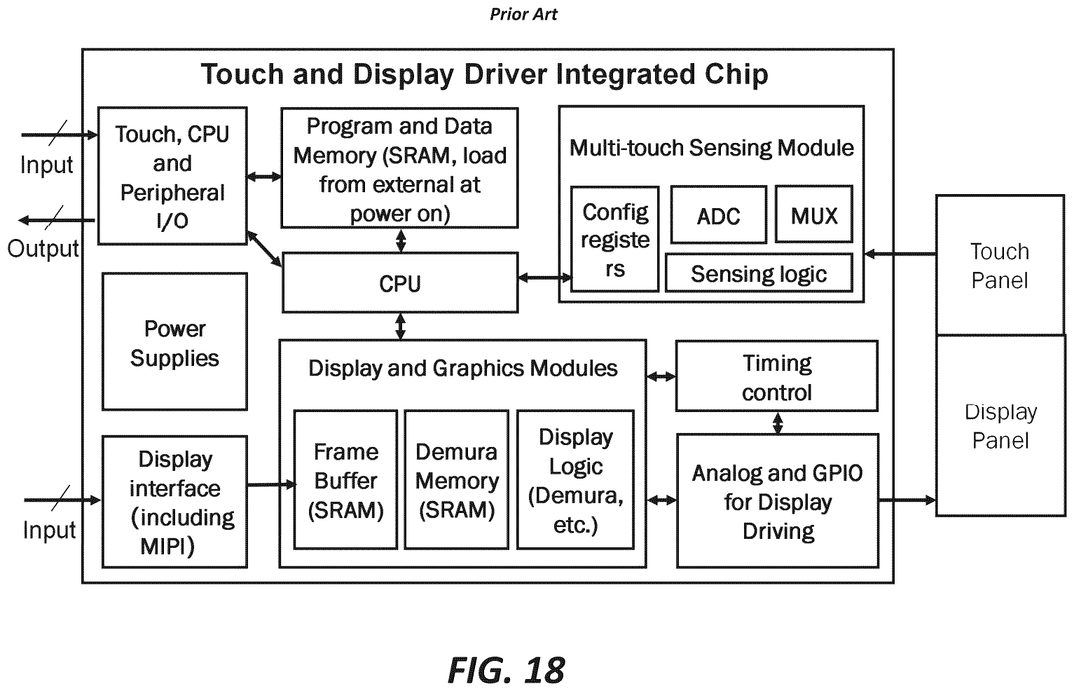

FIG. 18 illustrates a conventional touch and display driver integrated chip (TDDI) with embedded RAM. The TDDI includes a multi-touch sensing module that captures and processes user inputs from the touch panel. The multi-touch sensing module is composed of various components, including an analog-to-digital converter (ADC), multiplexer (MUX), and sensing logic. Configuration registers for these components are stored in a RAM embedded within the module. When user inputs are detected by the touch panel, the multi-touch sensing module processes the sensor data and sends it to the central processing unit (CPU) within the TDDI for further analysis. The RAM in the TDDI also stores additional program code and data, which are loaded from an external source when the device powers on. These programs and data allow the CPU to interpret the sensor input and generate corresponding image data for display.

The TDDI further includes a RAM-based frame buffer (may also be called frame memory) and a RAM-based Demura memory, both integral to the display and graphics module. The frame buffer temporarily holds the image data generated by the CPU before it is sent to the display, ensuring smooth and continuous rendering of the screen content. The demura memory is responsible for storing correction data used to adjust pixel inconsistencies, compensating for variations in brightness and color across the display panel. This Demura process ensures that the final image quality is uniform and free from distortions or irregularities.

Another component connected to the display and graphics module is a timing control module, which plays a crucial role in synchronizing the data flow between the display and the various components of the system. The timing control module ensures that the display refreshes at the appropriate intervals, avoiding glitches or screen tearing. It coordinates the operation of the frame buffer, demura memory, and the rest of the display components, allowing for precise control over the visual output on the display panel.

The display and graphics module is also linked to an analog and general-purpose input/output (GPIO) interface, which handles the conversion of digital data into analog signals necessary for driving the display. These signals are sent to the display panel, instructing it on how to render the image data. The GPIO facilitates communication with various peripheral components and allows for real-time adjustments to the display's operation, such as changes in brightness or contrast.

The display panel itself receives the analog signals from the GPIO and analog interface, which drive the individual pixels to render the final image. The timing control module ensures that the display panel refreshes the screen in accordance with the processed image data, delivering a smooth visual experience.

On the touch input side, the touch panel monitors for user interactions and sends sensor data to the multi-touch sensing module. The module processes the data using the ADC, MUX, and sensing logic, then forwards the interpreted data to the CPU. The CPU then generates image data based on the detected input, which is processed and stored in the frame buffer and Demura memory before being displayed on the screen.

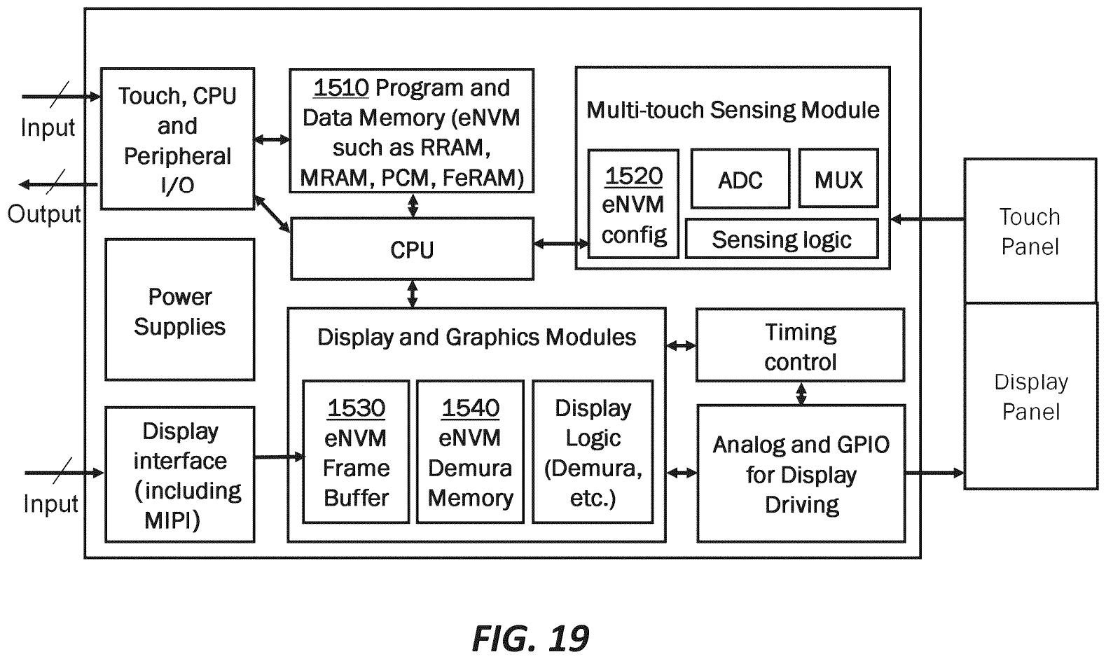

FIG. 19 illustrates an enhanced Touch and Display Driver Integrated Chip (TDDI) with embedded Non-Volatile Memory (NVM), according to one example embodiment. In this enhanced architecture, NVM may be integrated to replace various RAM-based components in the conventional TTDI in FIG. 18, including the demura memory, frame buffer, program and data memory, and configuration register memory in the multi-touch sensing module. The NVM used in these areas offers several technical advantages over traditional RAM, resulting in notable improvements in power efficiency, data retention, and system performance.

In some embodiments, the enhanced TDDI includes embedded NVM (eNVM) demura memory 1540, eNVM frame buffer 1530, eNVM configuration memory 1520, and eNVM program and data memory 1510. The use of eNVM in these components provides critical improvements over the conventional RAM-based architecture. NVM, unlike RAM, does not require continuous power to retain stored data, allowing the system to store key display and processing parameters without the need for constant refresh cycles. Additionally, by storing the demura correction data and frame buffer information in NVM, the display system can quickly recover these essential settings even after power-off events, eliminating the need to reload them from external memory.

For instance, in the conventional TTDI, the RAM-based demura memory stores correction data used to compensate for inconsistencies in pixel brightness and color across the display. This data must be continuously available to ensure uniform image quality. With the transition to eNVM, the luminance correction data is retained in the memory cells of the eNVM without power, ensuring that the display maintains its calibration without consuming additional energy. This feature is particularly beneficial for mobile devices with touch screens, where battery life is critical, as it minimizes power usage during idle periods or when the display is not actively refreshed.

Similarly, the eNVM frame buffer 1530 may replace the RAM-based frame buffer, which includes a plurality of memory cells that are preprogrammed to temporarily hold image data before it is sent to the display panel. In traditional designs, the frame buffer must be powered at all times to store and update the image data being prepared for display. With eNVM, the frame buffer can retain this data without the need for constant power, reducing the overall power consumption of the display subsystem. This is especially useful in scenarios where static images, such as notifications or AOD content, need to be displayed for extended periods without refreshing the entire display.

In the multi-touch sensing module, the eNVM configuration memory 1520 replaces the RAM-based configuration registers, where settings and calibration data for touch sensing are stored. By using NVM in this module, configuration settings can be permanently retained, even during power cycling or unexpected shutdowns, improving system reliability and reducing the need for re-initialization. This ensures that the touch panel can quickly resume normal operation without requiring recalibration or reloading of configuration data from external sources.

Additionally, the eNVM program and data memory 1510 may replace the RAM used to store program code and data. This enhancement allows the system to store essential operating instructions and data directly in NVM, ensuring they persist even when the device is powered off. This eliminates the need to reload the program and data memory from external storage during power-on sequences, enabling faster boot times and reducing power consumption associated with frequent memory accesses.

With this enhanced TTDI with eNVM, the analog and GPIO circuit may receive digital data from the display and graphics module, and convert the digital data into analog signals, and transmit the analog signals to the display panel for rendering. The digital data generated by the display and graphics module may be based on the demura correction data and the image data, in which the demura correction data may be used to adjust pixel inconsistencies, compensating for variations in brightness and color of the image data.

While examples and features of disclosed principles are described herein, modifications, adaptations, and other implementations are possible without departing from the spirit and scope of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

What is claimed is:

1. A circuitry for adjusting image data to-be rendered on a display device, comprising:
a non-volatile memory, comprising a plurality of memory cells configured to store luminance correction data and geometry correction data of the display device;
a luminance adjusting circuit configured to receive the luminance correction data from the non-volatile memory and adjust the image data based on the luminance correction data; and
a geometry adjusting circuit configured to receive the geometry correction data from the non-volatile memory and perform spatial manipulation of pixels in the image data based on the geometry correction data.

2. The circuitry of claim 1, wherein the plurality of memory cells in the non-volatile memory are further configured to store sub-pixel rendering correction data.

3. The circuitry of claim 2, further comprising:
a sub-pixel rendering circuit configured to increase an apparent resolution of the image data by adjusting each sub-pixel individually based on the sub-pixel rendering correction data.

4. The circuitry of claim 1, wherein the non-volatile memory array further comprises a serial data interface coupled to the luminance adjusting circuit and the geometry adjusting circuit.

5. The circuitry of claim 1, wherein the non-volatile memory array further comprises a parallel data interface coupled to the luminance adjusting circuit and the geometry adjusting circuit.

6. The circuitry of claim 1, wherein the luminance correction data comprises pixel-wise brightness and color correction data.

7. The circuitry of claim 1, wherein the geometry correction data is selected from a group consisting of shape information of the display device for Fringe adjustment, Foveation correction data for foveated display, and Wobulation correction data for wobulated display.

8. The circuitry of claim 7, wherein to perform the spatial manipulation of pixels, the geometry adjusting circuit is further configured to:
adjust pixel data at edges of the image data to align and fit the image data within the display device based on the shape information of the display device.

9. The circuitry of claim 7, wherein to perform the spatial manipulation of pixels, the geometry adjusting circuit is further configured to:
prioritize rendering high-resolution pixels in a foveal area corresponding to a center of a user's gaze, while rendering lower resolution in peripheral areas.

10. The circuitry of claim 7, wherein to perform the spatial manipulation of pixels, the geometry adjusting circuit is further configured to:
shift the image data in succession to increase an effective resolution of the image data on the display device, wherein the wobulation creates a perception of higher resolution than a native resolution of the display device.

11. The circuitry of claim 1, wherein the geometry correction data further comprises pixel-wise correction data for varifocal display and multi-focal display.

12. The circuitry of claim 1, wherein the non-volatile memory array includes one of a resistive random-access memory, a phase-change random access memory, a ferroelectric random-access memory, or a spin-transfer torque magnetic random-access memory.

13. The circuitry of claim 1, wherein the non-volatile memory array includes a redundant memory section configured to correct an error of the luminance data.

14. A circuitry for adjusting image data to-be rendered on a display device, comprising:
a non-volatile memory, comprising a plurality of memory cells configured to store luminance correction data and deburn-in correction data of the display device;
a luminance adjusting circuit configured to receive the luminance correction data from the non-volatile memory array and adjust the image data based on the luminance correction data; and
a deburn-in circuit configured to receive the deburn-in correction data from the non-volatile memory array and dynamically adjust pixel output of the image data to compensate for darkening or discoloration.

15. The circuitry of claim 14, wherein the deburn-in correction data comprises estimated pixel lifetimes generated based on analysis of appearance and usage patterns of the display device.

16. The circuitry of claim 14, wherein to dynamically adjust pixel output of the image data, the deburn-in circuit is further configured to:
modify a drive voltage and/or current supplied to each pixel, wherein the modification is performed to restore intended luminance and color balance of each pixel.

17. The circuitry of claim 14, wherein the deburn-in circuit is further configured to:
apply stress to underused pixels during idle periods of the display device by increasing a current or maintaining the pixels in an active state for a prolonged duration to accelerate aging of the underused pixels.

18. A circuitry in an electronic device supporting an always-on-display (AOD) mode, comprising:
a screen;
a non-volatile memory array (NVM) configured to store AOD information being displayed on the display panel in the AOD mode, wherein the AOD information comprises static content to be displayed during the AOD mode;
a random-access memory (RAM) configured to receive image data to be displayed on the screen in a non-AOD mode;
one or more processors; and
a memory storing instructions which, when executed by the one or more processors, cause the circuitry to:
selectively activate a subset of the plurality of pixels on the display panel based on the AOD information, wherein remaining pixels on the display panel are deactivated during the AOD mode to reduce power consumption.

19. The circuitry of claim 18, wherein the NVM is further configured to store multiple predefined AOD display configurations, and the circuitry is configured to switch between the predefined AOD display configurations based on the device status information, including battery level, usage patterns, or time of day.

20. A circuitry for a touch and display panel, comprising:
a touch sensing module configured to receive user touch input from the touch and display panel, wherein the user touch input corresponds to image data to be displayed on the touch and display panel;
a display module comprising a first non-volatile memory array and a second non-volatile memory array, wherein:
the first non-volatile memory array comprises a plurality of memory cells preprogrammed to store luminance correction data,
the second non-volatile memory array comprises a plurality of memory cells configured to receive and store the image data to be displayed on the touch and display panel, and
a logic circuit configured to generate digital data based on the luminance correction data and the image data;
an input/output interface configured to convert the digital data into analog data and output the analog data to the touch and display panel for rendering.
